(19) United States
(12) Patent Application Publication
(10) Pub. No.: US 2026/0190620 A1
(43) Pub. Date: Jul. 2, 2026

(54) Display Substrate and Manufacturing Method Therefor, and Display Apparatus

(71) Applicants: Beijing BOE Technology Development Co., Ltd., Beijing (CN); BOE Technology Group Co., Ltd., Beijing (CN)

(72) Inventors: Zhuo LI, Beijing (CN); Dongni LIU, Beijing (CN); Ming YANG, Beijing (CN); Minghua XUAN, Beijing (CN); Xuan FENG, Beijing (CN); Seungwoo HAN, Beijing (CN); Liwei LIU, Beijing (CN); Hui ZHANG, Beijing (CN); Dingchang ZHANG, Beijing (CN)

(21) Appl. No.: 18/863,342

(22) PCT Filed: Aug. 15, 2024
(86) PCT No.: PCT/CN2024/112303

§ 371 Date: Nov. 6, 2024

(30) Foreign Application Priority Data
Sep. 14, 2023 (CN) 202311189780.4

(51) Int. Cl. H10K 59/121; H10K 59/12

(52) U.S. Cl. CPC H10K 59/1213; H10K 59/1201; H10K 59/1216

(57) ABSTRACT

A display substrate includes a plurality of circuit units. A circuit unit includes a pixel drive circuit, and the pixel drive circuit includes a plurality of transistors. In a direction perpendicular to a plane of the display substrate, the display substrate includes a first conductive layer, a semiconductor layer, a second conductive layer and a third conductive layer arranged on a base substrate. The first conductive layer includes at least one first adapter electrode, the semiconductor layer includes active layers of a plurality of transistors, the second conductive layer includes at least one second adapter electrode, and the third conductive layer includes at least one third adapter electrode.

### CROSS-REFERENCE TO RELATED APPLICATIONS

This application is a national stage application of PCT Application No. PCT/CN2024/112303, which is filed on Aug. 15, 2024 and claims priority to Chinese Patent Application No. 202311189780.4 filed to the CNIPA on Sep. 14, 2023 and entitled “Display Substrate and Manufacturing Method Therefor, and Display Apparatus”, contents of which should be construed as being incorporated into the present application by reference.

### TECHNICAL FIELD

The present disclosure relates to, but is not limited to, the field of display technologies, and particularly to a display substrate and a manufacturing method therefor, and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of claims.

In one aspect, the present disclosure provides a display substrate, including a plurality of circuit units, wherein at least one circuit unit includes a pixel drive circuit, and the pixel drive circuit at least includes a plurality of transistors; in a direction perpendicular to a plane of the display substrate, the display substrate at least includes a first conductive layer, a semiconductor layer, a second conductive layer and a third conductive layer arranged on a base substrate and sequentially arranged in a direction away from the base substrate, the first conductive layer includes at least one first adapter electrode, the semiconductor layer includes active layers of a plurality of transistors, the second conductive layer includes at least one second adapter electrode, and the third conductive layer includes at least one third adapter electrode; the second adapter electrode is simultaneously connected to the first adapter electrode and an active layer of one transistor through an adapter structure via, the third adapter electrode is connected to an active layer of another transistor through a single-hole structure via, the adapter structure via includes a deep half hole and a shallow half hole, the deep half hole exposes the first adapter electrode, and the shallow half hole exposes the active layers.

In an exemplary implementation, the plurality of transistors at least include a first transistor, the first transistor at least includes a first active layer, and the first active layer is arranged in the semiconductor layer; and the first conductive layer includes a first connection electrode which serves as the first adapter electrode, the second conductive layer further includes an initial signal line, and the initial signal line is simultaneously connected to the first connection electrode and the first active layer through an adapter structure via.

In an exemplary implementation, the plurality of transistors at least include a first transistor, the first transistor at least includes a first active layer, and the first active layer is arranged in the semiconductor layer; and the third conductive layer further includes an initial signal line, and the initial signal line is connected to the first active layer through a single-hole structure via.

In an exemplary implementation, the plurality of transistors at least include a second transistor, the second transistor at least includes a second active layer, and the second active layer is arranged in the semiconductor layer; and the first conductive layer includes a second connection electrode which serves as the first adapter electrode, the second conductive layer includes a fifth connection electrode which serves as the second adapter electrode, and the fifth connection electrode is simultaneously connected to the second connection electrode and the second active layer through an adapter structure via.

In an exemplary implementation, the plurality of transistors at least include a fourth transistor, the fourth transistor at least includes a fourth active layer, and the fourth active layer is arranged in the semiconductor layer; and the first conductive layer further includes a data signal line, the second conductive layer includes a sixth connection electrode which serves as the second adapter electrode, and the sixth connection electrode is simultaneously connected to the data signal line and the fourth active layer through an adapter structure via.

In an exemplary implementation, the plurality of transistors at least include a fifth transistor, the fifth transistor at least includes a fifth active layer, and the fifth active layer is arranged in the semiconductor layer; and the first conductive layer further includes a first power supply line, the second conductive layer includes a seventh connection electrode which serves as the second adapter electrode, and the seventh connection electrode is simultaneously connected to the first power supply line and the fifth active layer through an adapter structure via.

In an exemplary implementation, the plurality of transistors at least include a fifth transistor, the fifth transistor at least includes a fifth active layer, and the fifth active layer is arranged in the semiconductor layer; and the third conductive layer further includes a first power supply line, and the first power supply line is connected to the fifth active layer through a single-hole structure via.

In an exemplary implementation, the plurality of transistors at least include a sixth transistor, the sixth transistor at least includes a sixth active layer, and the sixth active layer is arranged in the semiconductor layer; and the third conductive layer includes an anode connection electrode which serves as the third adapter electrode, and the anode connection electrode is connected to the sixth active layer through a single-hole structure via.

In an exemplary implementation, the plurality of transistors at least include a seventh transistor, the seventh transistor at least includes a seventh active layer, and the seventh active layer is arranged in the semiconductor layer; and the first conductive layer further includes a first power supply line, the second conductive layer includes an eighth connection electrode which serves as the second adapter electrode, and the eighth connection electrode is simultaneously connected to the first power supply line and the seventh active layer through an adapter structure via.

In an exemplary implementation, the plurality of transistors at least include a seventh transistor, the seventh transistor at least includes a seventh active layer, and the seventh active layer is arranged in the semiconductor layer; and the third conductive layer further includes a first power supply line, and the first power supply line is connected to the seventh active layer through a single-hole structure via.

In an exemplary implementation, at least one transistor includes a gate electrode, and the gate electrode is arranged in the second conductive layer.

In an exemplary implementation, the pixel drive circuit further includes a storage capacitor, the storage capacitor at least includes a first electrode plate arranged in the first conductive layer, a second electrode plate arranged in the second conductive layer, and a third electrode plate arranged in the third conductive layer, an orthographic projection of the second electrode plate on a plane of the base substrate at least partially overlaps with an orthographic projection of the first electrode plate on the plane of the base substrate, an orthographic projection of the third electrode plate on the plane of the base substrate at least partially overlaps with the orthographic projection of the second electrode plate on the plane of the base substrate, and the first electrode plate is connected to the third electrode plate.

In an exemplary implementation, at least one circuit unit further includes at least one power supply connection line extending in a first direction and at least one first power supply line extending in a second direction, the first power supply line is connected to the power supply connection line to form a net-like connecting structure that transmits a first power supply signal, and the first direction intersects the second direction.

In an exemplary implementation, the first power supply line is arranged in the first conductive layer, the power supply connection line is arranged in the third conductive layer, the second conductive layer includes an eighth connection electrode which serves as the second adapter electrode, the eighth connection electrode is connected to the first power supply line through a via, and the power supply connection line is connected to the eighth connection electrode through a via.

In an exemplary implementation, the first power supply line and the power supply connection line are arranged on a same layer and are connected to each other to form an integrated structure.

In another aspect, a display apparatus is also provided in the present disclosure, and the display apparatus includes the display substrate described above.

In yet another aspect, the present disclosure also provides a method for manufacturing a display substrate, wherein the display substrate includes a plurality of circuit units, at least one circuit unit includes a pixel drive circuit, and the pixel drive circuit at least includes a plurality of transistors; the method including:
forming a first conductive layer, a semiconductor layer, a second conductive layer and a third conductive layer sequentially on a base substrate and in a direction away from the base substrate, wherein the first conductive layer includes at least one first adapter electrode, the semiconductor layer includes active layers of a plurality of transistors, the second conductive layer includes at least one second adapter electrode, and the third conductive layer includes at least one third adapter electrode; the second adapter electrode is simultaneously connected to the first adapter electrode and the active layer of one transistor through an adapter structure via, the third adapter electrode is connected to the active layer of another transistor through a single-hole structure via, the adapter structure via includes a deep half hole and a shallow half hole, the deep half hole exposes the first adapter electrode, and the shallow half hole exposes the active layer.

Other aspects of the present disclosure may be comprehended after the drawings and the detailed descriptions are read and understood.

### BRIEF DESCRIPTION OF DRAWINGS

Accompany drawings are used to provide understanding of technical solutions of the present disclosure, and form a part of the specification. The accompany drawings and in embodiments of the present disclosure are adopted to explain the technical solutions of the present disclosure, and do not form limitations on the technical solutions of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit according to an exemplary embodiment of the present disclosure.

FIG. 5 is a schematic diagram of a planar structure of a display substrate according to an exemplary embodiment of the present disclosure.

FIG. 6 is a sectional view taken in an A-A direction in FIG. 5.

FIGS. 7A and 7B are schematic diagrams of a display substrate after a pattern of a first conductive layer is formed, according to the present disclosure.

FIGS. 8A, 8B and 8C are schematic diagrams of a display substrate after a pattern of a semiconductor layer is formed according to the present disclosure.

FIGS. 9A and 9B are schematic diagrams of a display substrate after a pattern of a second insulating layer is formed according to the present disclosure.

FIGS. 10A, 10B, 10C and 10D are schematic diagrams of a display substrate after a pattern of a second conductive layer is formed according to the present disclosure.

FIGS. 11A and 11B are schematic diagrams of a display substrate after a pattern of a third insulating layer is formed according to the present disclosure.

FIGS. 12A and 12B are schematic diagrams of a display substrate after a pattern of a third conductive layer is formed, according to the present disclosure.

FIG. 13 is a schematic diagram of a planar structure of another display substrate according to an exemplary embodiment of the present disclosure.

FIG. 14 is a schematic diagram of another display substrate after a pattern of a first conductive layer is formed according to the present disclosure.

FIG. 15A and FIG. 15B are schematic diagrams of another display substrate after a pattern of a semiconductor layer is formed according to the present disclosure.

FIG. 16 is a schematic diagram of another display substrate after a pattern of a second insulating layer is formed according to the present disclosure.

FIGS. 17A and 17B are schematic diagrams of another display substrate after a pattern of a second conductive layer is formed, according to the present disclosure.

FIG. 18 is a schematic diagram of another display substrate after a pattern of a third insulating layer is formed according to the present disclosure.

FIGS. 19A and 19B are schematic diagrams of another display substrate after a pattern of a third conductive layer is formed, according to the present disclosure.

FIG. 20 is a schematic diagram of a planar structure of yet another display substrate according to an exemplary embodiment of the present disclosure.

FIG. 21 is a schematic diagram of yet another display substrate after a pattern of a first conductive layer is formed according to the present disclosure.

FIG. 22A and FIG. 22B are schematic diagrams of another display substrate after a pattern of a semiconductor layer is formed according to the present disclosure.

FIG. 23 is a schematic diagram of another display substrate after a pattern of a second insulating layer is formed according to the present disclosure.

FIGS. 24A and 24B are schematic diagrams of yet another display substrate after a pattern of a second conductive layer is formed, according to the present disclosure.

FIG. 25 is a schematic diagram of yet another display substrate after a pattern of a third insulating layer is formed according to the present disclosure.

FIG. 26A and FIG. 26B are schematic diagrams of another display substrate after a pattern of a third conductive layer is formed according to the present disclosure.

### DETAILED DESCRIPTION

To make objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc. In the present disclosure, “about” refers to that a boundary is not defined so strictly and numerical values within a range of process and measurement errors are allowed.

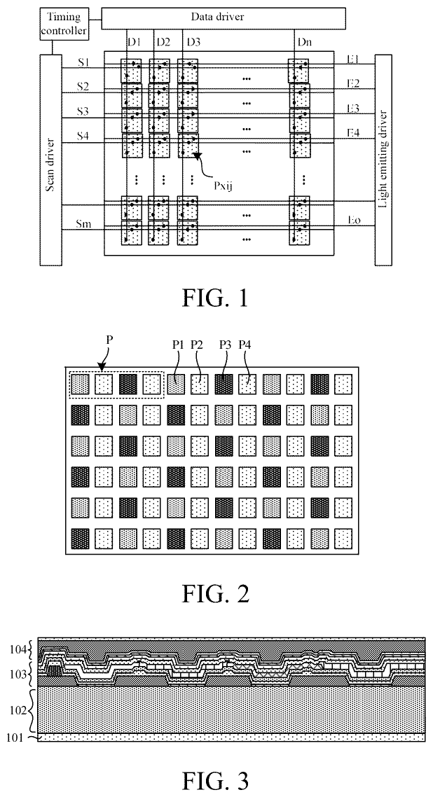

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation mode, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation mode, the pixel array may be arranged on a display substrate.

FIG. 2 is a schematic diagram of a planar structure of a display substrate. As shown in FIG. 2, the display substrate may include a plurality of pixel units P arranged in a matrix, and at least one of the pixel units P may include a first sub-pixel P1, a second sub-pixel P2, a third sub-pixel P3, and a fourth sub-pixel P4. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. The light emitting unit may include a light emitting device connected to a pixel drive circuit of a sub-pixel where the light emitting device is located, and the light emitting device is configured to emit light with corresponding brightness in response to a current output by the pixel drive circuit of the sub-pixel where the light emitting device is located.

In an exemplary implementation, the first sub-pixels P1 may be red sub-pixels (R) emitting red light, the second sub-pixels P2 and the fourth sub-pixels P4 may be green sub-pixels (G) emitting green light, and the third sub-pixels P3 may be blue sub-pixels (B) emitting blue light. In an exemplary implementation, a sub-pixel may be in a shape of a rectangle, a rhombus, a pentagon, or a hexagon. Four sub-pixels may be arranged in a manner to stand side by side horizontally, in a manner to stand side by side vertically, or in a square-shaped arrangement, etc., which is not limited here in the present disclosure.

In an exemplary implementation, a pixel unit may include three sub-pixels, and the three sub-pixels may be arranged side by side horizontally, side by side vertically, or in a delta-shaped arrangement, which is not limited here in the present disclosure.

FIG. 3 is a schematic diagram of a sectional structure of a display substrate, illustrating a structure of four sub-pixels in a display region. As shown in FIG. 3, on a plane perpendicular to the display substrate, the display substrate may include a drive circuit layer 102 arranged on a base substrate 101, a light emitting structure layer 103 arranged on a side of the drive circuit layer 102 away from the base substrate 101, and an encapsulation structure layer 104 arranged on a side of the light emitting structure layer 103 away from the base substrate 101. In some possible implementation modes, the display substrate may include another film layer, such as a touch structure layer, which is not limited here in the present disclosure.

In an exemplary implementation mode, the base substrate 101 may be a flexible base substrate, or may be a rigid base substrate. The drive circuit layer 102 may include a plurality of circuit units, each of which may at least include a pixel drive circuit composed of a plurality of transistors and a storage capacitor. The light emitting structure layer 103 may include a plurality of light emitting units, each light emitting unit may include a light emitting device, and the light emitting device may at least include an anode, an organic emitting layer and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation structure layer 104 may include a first encapsulation structure layer, a second encapsulation structure layer, and a third encapsulation structure layer that are stacked. The first encapsulation structure layer and the third encapsulation structure layer may be made of an inorganic material, the second encapsulation structure layer may be made of an organic material, and the second encapsulation structure layer is arranged between the first encapsulation structure layer and the third encapsulation structure layer to form a laminated structure of inorganic material/organic material/inorganic material and ensure that external moisture cannot enter the light emitting structure layer 103.

A display substrate is provided in an exemplary embodiment of the present disclosure. In an exemplary implementation mode, on a plane perpendicular to the display substrate, the display substrate may include a drive structure layer arranged on a base substrate and a light emitting structure layer arranged on a side of the drive structure layer away from the base substrate. On a plane parallel to the display substrate, the drive structure layer may include a plurality of circuit units constituting a plurality of unit rows and a plurality of unit columns, and at least one of the circuit units may include a pixel drive circuit configured to output a corresponding current to a light emitting device connected to the pixel drive circuit. The light emitting structure layer may include a plurality of light emitting units, at least one of the light emitting units may include a light emitting device connected to a pixel drive circuit of a corresponding circuit unit. The light emitting device is configured to emit light with corresponding brightness in response to a current output by a pixel drive circuit connected to the light emitting device.

In an exemplary implementation mode, circuit units mentioned in the present disclosure refer to regions divided according to pixel drive circuits, and light emitting units mentioned in the present disclosure refer to regions divided according to light emitting devices. In an exemplary implementation mode, a position and a shape of an orthographic projection of a light emitting unit on the base substrate may correspond to a position and a shape of an orthographic projection of a circuit unit on the base substrate, or a position and a shape of an orthographic projection of a light emitting unit on the base substrate may not correspond to a position and a shape of an orthographic projection of a circuit unit on the base substrate.

An exemplary embodiment of the present disclosure provides a display substrate, including a plurality of circuit units, wherein at least one circuit unit includes a pixel drive circuit, and the pixel drive circuit at least includes a plurality of transistors; in a direction perpendicular to a plane of the display substrate, the display substrate at least includes a first conductive layer, a semiconductor layer, a second conductive layer and a third conductive layer arranged on a base substrate and sequentially arranged in a direction away from the base substrate, the first conductive layer includes at least one first adapter electrode, the semiconductor layer includes active layers of a plurality of transistors, the second conductive layer includes at least one second adapter electrode, and the third conductive layer includes at least one third adapter electrode; the second adapter electrode is simultaneously connected to the first adapter electrode and the active layer of one transistor through an adapter structure via, the third adapter electrode is connected to the active layer of another transistor through a single-hole structure via, the adapter structure via includes a deep half hole and a shallow half hole, the deep half hole exposes the first adapter electrode, and the shallow half hole exposes the active layer.

In an exemplary implementation, the plurality of transistors at least include a first transistor, the first transistor at least includes a first active layer, and the first active layer is arranged in the semiconductor layer. The first conductive layer includes a first connection electrode which serves as the first adapter electrode, and the second conductive layer further includes an initial signal line that is simultaneously connected to the first connection electrode and the first active layer through an adapter structure via, or the third conductive layer further includes an initial signal line that is connected to the first active layer through a single-hole structure via.

In an exemplary implementation, the plurality of transistors at least include a second transistor, the second transistor at least includes a second active layer, and the second active layer is arranged in the semiconductor layer. The first conductive layer includes a second connection electrode which serves as the first adapter electrode, the second conductive layer includes a fifth connection electrode which serves as the second adapter electrode, and the fifth connection electrode is simultaneously connected to the second connection electrode and the second active layer through an adapter structure via.

In an exemplary implementation, the plurality of transistors at least include a fourth transistor, the fourth transistor at least includes a fourth active layer, and the fourth active layer is arranged in the semiconductor layer. The first conductive layer further includes a data signal line, the second conductive layer includes a sixth connection electrode which serves as the second adapter electrode, and the sixth connection electrode is simultaneously connected to the data signal line and the fourth active layer through an adapter structure via.

In an exemplary implementation, the plurality of transistors at least include a fifth transistor, the fifth transistor at least includes a fifth active layer, and the fifth active layer is arranged in the semiconductor layer. The first conductive layer further includes a first power supply line, the second conductive layer includes a seventh connection electrode which serves as the second adapter electrode, and the seventh connection electrode is simultaneously connected to the first power supply line and the fifth active layer through an adapter structure via, or the third conductive layer further includes a first power supply line that is connected to the fifth active layer through a single-hole structure via.

In an exemplary implementation, the plurality of transistors at least include a sixth transistor, the sixth transistor at least includes a sixth active layer, and the sixth active layer is arranged in the semiconductor layer. The third conductive layer includes an anode connection electrode which serves as the third adapter electrode, and the anode connection electrode is connected to the sixth active layer through a single-hole structure via.

In an exemplary implementation, the plurality of transistors at least include a seventh transistor, the seventh transistor at least includes a seventh active layer, and the seventh active layer is arranged in the semiconductor layer. The first conductive layer further includes a first power supply line, the second conductive layer includes an eighth connection electrode which serves as the second adapter electrode, and the eighth connection electrode is simultaneously connected to the first power supply line and the seventh active layer through an adapter structure via, or the third conductive layer further includes a first power supply line that is connected to the seventh active layer through a single-hole structure via.

In an exemplary implementation, at least one transistor includes a gate electrode, and the gate electrode is arranged in the second conductive layer.

The display substrate of the present embodiment will now be described through some examples.

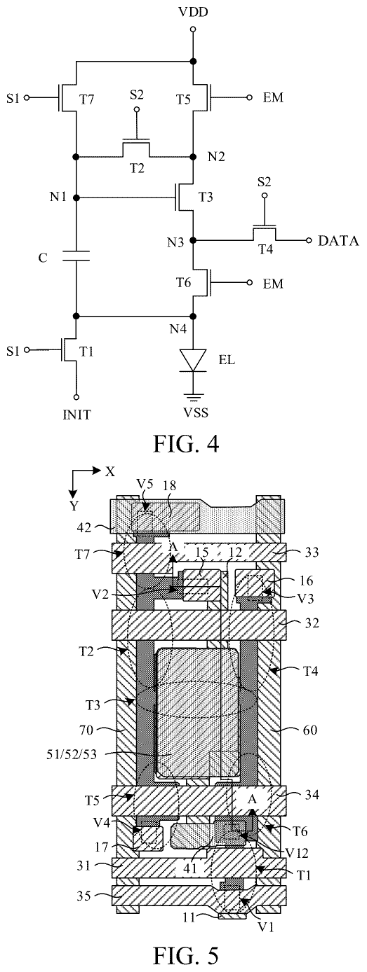

FIG. 4 is an equivalent circuit diagram of a pixel drive circuit according to an exemplary embodiment of the present disclosure. As shown in FIG. 4, in an exemplary implementation, the pixel drive circuit according to an exemplary embodiment of the present disclosure adopts a 7T1C structure, in which the pixel drive circuit may include seven transistors (a first transistor T1 to a seventh transistor T7) and one storage capacitor C, and the pixel drive circuit is connected to six signal lines (a first scan signal line S1, a second scan signal line S2, a light emitting signal line EM, an initial signal line INIT, a data signal line DATA and a first power supply line VDD).

In an exemplary implementation, the pixel drive circuit may include a first node N1, a second node N2, a third node N3, and a fourth node N4. The first node N1 is connected to a first electrode of the second transistor T2, a gate electrode of the third transistor T3, a second electrode of the seventh transistor T7 and a first terminal of the storage capacitor C; the second node N2 is connected to a second electrode of the second transistor T2, a first electrode of the third transistor T3 and a second electrode of the fifth transistor T5; the third node N3 is connected to a second electrode of the third transistor T3, a second electrode of the fourth transistor T4 and a first electrode of the sixth transistor T6; and the fourth node N4 is connected to a second electrode of the first transistor T1, a second electrode of the sixth transistor T6 and a second terminal of the storage capacitor C.

In an exemplary implementation, the first terminal of the storage capacitor C is connected to the first node N1, and the second terminal of the storage capacitor C is connected to the fourth node N4.

In an exemplary implementation, the gate electrode of the first transistor T1 is connected to the first scan signal line S1, the first electrode of the first transistor T1 is connected to the initial signal line INIT, and the second electrode of the first transistor T1 is connected to the fourth node N4. When a turn-on signal is applied to the first scan signal line S1, the first transistor T1 is turned on to transmit an initialization voltage to the fourth node N4 to initialize the second terminal of the storage capacitor C and a first electrode of a light emitting device EL.

In an exemplary implementation, the gate electrode of the second transistor T2 is connected to the second scan signal line S2, the first electrode of the second transistor T2 is connected to the first node N1, and the second electrode of the second transistor T2 is connected to the second node N2. When a turn-on signal is applied to the second scan signal line S2, the second transistor T2 connects the first node N1 and the second node N2.

In an exemplary implementation, the gate electrode of the third transistor T3 is connected to the first node N1, the first electrode of the third transistor T3 is connected to the second node N2, and the second electrode of the third transistor T3 is connected to the third node N3. The third transistor T3 may be referred to as a drive transistor, and the third transistor T3 determines a size of a drive current flowing between the first power supply line VDD and the light emitting device EL according to a potential difference between the gate electrode and the first electrode of the third transistor T3.

In an exemplary implementation, the gate electrode of the fourth transistor T4 is connected to the second scan signal line S2, the first electrode of the fourth transistor T4 is connected to the data signal line DATA, and the second electrode of the fourth transistor T4 is connected to the third node N3. When a turn-on signal is applied to the second scan signal line S2, the fourth transistor T4 inputs a data voltage of the data signal line DATA to the third node N3.

In an exemplary implementation, the gate electrode of the fifth transistor T5 is connected to the light emitting signal line EM, the first electrode of the fifth transistor T5 is connected to the first power supply line VDD, and the second electrode of the fifth transistor T5 is connected to the second node N2. The gate electrode of the sixth transistor T6 is connected to the light emitting signal line EM, the first electrode of the sixth transistor T6 is connected to the third node N3, and the second electrode of the sixth transistor T6 is connected to the fourth node N4. When a turn-on signal is applied to the light emitting signal line EM, the fifth transistor T5 and the sixth transistor T6 form a drive current path between the first power supply line VDD and the light emitting device EL to cause the light emitting device EL to emit light.

In an exemplary implementation, the gate electrode of the seventh transistor T7 is connected to the first scan signal line S1, the first electrode of the seventh transistor T7 is connected to the first power supply line VDD, and the second electrode of the seventh transistor T7 is connected to the first node N1. When a turn-on signal is applied to the first scan signal line S1, the seventh transistor T7 is turned on to transmit a first power supply voltage to the first node N1.

In an exemplary implementation, the light emitting device EL may be an OLED including a first electrode (anode), an organic light emitting layer, and a second electrode (cathode), which are stacked, or may be a QLED including a first electrode (anode), a quantum dot light emitting layer, and a second electrode (cathode), which are stacked. The first electrode of the light emitting device EL is connected to the fourth node N4, and a second electrode of the light emitting device EL is connected to the second power supply line VSS.

In an exemplary implementation, the signal of the first power supply line VDD is a continuously supplied high-level signal, the signal of the second power supply line VSS is a continuously supplied low-level signal, the first power supply line VDD may be configured to provide a constant first voltage signal to the pixel drive circuit, the second power supply line VSS may be configured to provide a constant second voltage signal to the light emitting device EL, the first voltage signal is greater than the second voltage signal, and the initial signal line INIT may be configured to provide an initial voltage signal to the pixel drive circuit. The initial voltage signal may be a constant voltage signal which may be between a first voltage signal provided by the first power supply line VDD and a second voltage signal provided by the second power supply line VSS, which is not limited here in the present disclosure.

In an exemplary implementation, the seven transistors of the pixel drive circuit may be N-type transistors, or may be P-type transistors. Use of a same type of transistors in a pixel drive circuit may simplify a process flow, reduce process difficulties of the display substrate, and improve a yield of products.

In an exemplary implementation, the first transistor T1 to the seventh transistor T7 in each pixel drive circuit may be low-temperature polysilicon transistors or oxide transistors. An active layer of an oxide transistor may be made of an oxide semiconductor (Oxide). Oxide thin film transistors have the advantages of high electron mobility, low working voltage, low leakage characteristics, etc., and the use of a display substrate equipped with oxide thin film transistors can achieve low-frequency drive, reduce power consumption and improve display quality.

In an exemplary implementation, the first transistor T1 to the seventh transistor T7 of the pixel drive circuit may adopt low-temperature polysilicon transistors and metal oxide transistors, and the low-temperature polysilicon transistors and the oxide transistors are integrated on one display substrate to form a low temperature polycrystalline oxide (LTPO) display substrate, so that the advantages of both the low-temperature polysilicon transistors and the oxide transistors can be utilized to achieve low-frequency drive, reduce power consumption and improve display quality.

In an exemplary implementation, taking a case that the first transistor T1 to the seventh transistor T7 included in the pixel drive circuit are all N-type transistors as an example, a working process of the pixel drive circuit may include following stages.

A first stage A1 is referred to as an initialization stage. The first scan signal line S1 provides a high-level signal to turn on the first transistor T1 and the seventh transistor T7. The first transistor T1 is turned on so that the initial voltage signal provided by the initial signal line INIT is provided to the fourth node N4 to initialize the second terminal of the storage capacitor C and the first electrode of the light emitting device EL to clear the original data voltage in the storage capacitor C and clear a pre-stored voltage of the first electrode of the light emitting device EL, thereby completing initialization. The seventh transistor T7 is turned on so that the first voltage signal output from the first power supply line VDD is provided to the first node N1 through the seventh transistor T7 and charged to the first terminal of the storage capacitor C. Since the first terminal of the storage capacitor C is at a high level, the third transistor T3 is turned on.

A second stage A2 is referred to as a data writing stage or a threshold compensation stage. The second scan signal line S2 provides a high-level signal to turn on the second transistor T2 and the fourth transistor T4. The second transistor T2 is turned on so that the first node N1 and the second node N2 are connected, and the fourth transistor T4 is turned on so that the data voltage output from the data signal line DATA is provided to the first node N1 through the third node N3, the turned-on third transistor T3, the second node N2 and the turned-on second transistor T2, and a difference between the data voltage output from the data signal line DATA and a threshold voltage of the third transistor T3 is charged into the first terminal of the storage capacitor C.

The third stage A3 is referred to as a light emitting stage. The light emitting signal line EM provides a high-level signal, so that the fifth transistor T5 and the sixth transistor T6 are turned on, and the first voltage signal output by the first power supply line VDD provides a drive voltage to the first electrode of the light emitting device EL through the turned-on fifth transistor T5, the third transistor T3 and the sixth transistor T6 to drive the light emitting device EL to emit light.

In a drive process of the pixel drive circuit, the current flowing through the light emitting device EL is independent of the threshold voltage of the third transistor T3, so that the pixel drive circuit can better compensate the threshold voltage of the third transistor T3.

FIG. 5 is a schematic diagram of a planar structure of a display substrate according to an exemplary embodiment of the present disclosure, illustrating a structure of one circuit unit. On a plane parallel to the display substrate, the display substrate may include a plurality of circuit units constituting a plurality of unit rows and a plurality of unit columns, and at least one circuit unit may include a pixel drive circuit. As shown in FIG. 5, the pixel drive circuit is connected to the first scan signal line 31, the second scan signal line 32, the third scan signal line 33, the light emitting signal line 34, the initial signal line 35, the data signal line 60 and the first power supply line 70. The first scan signal line 31, the second scan signal line 32 and the third scan signal line 33 are configured to provide scan signals to the pixel drive circuit, the light emitting signal line 34 is configured to provide a light emission control signal to the pixel drive circuit, and the initial signal line 35, the data signal line 60 and the first power supply line 70 are configured to provide an initial signal, a first power supply signal and a data signal to the pixel drive circuit.

In an exemplary implementation, main body portions of the first scan signal line 31, the second scan signal line 32, the third scan signal line 33, the light emitting signal line 34 and the initial signal line 35 may be in a shape of a straight line or a polyline extending in a first direction X, and main body portions of the data signal line 60 and the first power supply line 70 may be in a shape of a straight line or a polyline extending in a second direction Y, the first direction X intersecting the second direction Y.

In the present disclosure, “A extends in a B direction” refers to that A may include a main portion and a secondary portion connected to the main portion, wherein the main portion is a line, a line segment, or a strip-shaped body, the main portion extends in the B direction, and a length of the main portion extending in the B direction is greater than a length of the secondary portion extending in another direction. In following description, “A extends in a B direction” means “a main body portion of A extends in a B direction”. In an exemplary implementation, the first direction X may be the unit row direction, and the second direction Y may be the unit column direction.

In an exemplary implementation, the pixel drive circuit may at least include a storage capacitor and a plurality of transistors, the plurality of transistors may include a first transistor T1, a second transistor T2, a third transistor T3, a fourth transistor T4, a fifth transistor T5, a sixth transistor T6 and a seventh transistor T7, and the storage capacitor may include a first electrode plate 51, a second electrode plate 52 and a third electrode plate 53 which are stacked.

In an exemplary implementation, the first transistor T1 to the seventh transistor T7 may be low-temperature polysilicon transistors, or may be oxide transistors.

In an exemplary implementation, the gate electrode of the first transistor T1 is connected to the first scan signal line 31, the gate electrode of the second transistor T2 and the gate electrode of the fourth transistor T4 are connected to the second scan signal line 32, the gate electrode of the seventh transistor T7 is connected to the third scan signal line 33, and the gate electrode of the fifth transistor T5 and the gate electrode of the sixth transistor T6 are connected to the light emitting signal line 34.

In an exemplary implementation, the first electrode of the first transistor T1 is connected to the initial signal line 35, the first electrode of the fourth transistor T4 is connected to the data signal line 60, the first electrode of the fifth transistor T5 is connected to the first power supply line 70, and the first electrode of the seventh transistor T7 is connected to the first power supply line 70.

In an exemplary implementation, in a direction perpendicular to a base substrate, the display substrate may include a first conductive layer, a semiconductor layer, a second conductive layer and a third conductive layer arranged on the base substrate and sequentially arranged in a direction away from the base substrate, the first electrode plate 51 of the storage capacitor, the data signal line 60 and the first power supply line 70 may be arranged in the first conductive layer, the active layers of the first transistor T1 to the seventh transistor T7 may be arranged in the semiconductor layer, the first scan signal line 31, the second scan signal line 32, the third scan signal line 33, the light emitting signal line 34, the initial signal line 35 and the second electrode plate 52 of the storage capacitor may be arranged in the second conductive layer, and the third electrode plate 53 of the storage capacitor may be arranged in the third conductive layer.

In an exemplary implementation, the first conductive layer may further include at least one first adapter electrode, the second conductive layer may further include at least one second adapter electrode, and the third conductive layer may further include at least one third adapter electrode.

In an exemplary implementation, the second adapter electrode in the second conductive layer may be simultaneously connected to the first adapter electrode in the first conductive layer and the active layer of one transistor in the semiconductor layer through an adapter structure via, and the third adapter electrode in the third conductive layer may be connected to the active layer of another transistor in the semiconductor layer through a single-hole structure via.

In an exemplary implementation, the adapter structure via may include a deep half hole and a shallow half hole, the deep half hole exposes the first adapter electrode in the first conductive layer, and the shallow half hole exposes the active layers in the semiconductor layer. The single-hole structure via may include one via that merely exposes the active layers in the semiconductor layer.

In an exemplary implementation, the first transistor T1 at least includes a first active layer, and the first active layer is arranged in the semiconductor layer. The first conductive layer may include a first connection electrode 11 which serves as the first adapter electrode, and the initial signal line 35 in the second conductive layer may be simultaneously connected to the first connection electrode 11 in the first conductive layer and the first active layer in the semiconductor layer through a first via V1 which serves as an adapter structure via.

In an exemplary implementation, the second transistor T2 at least includes a second active layer, and the second active layer is arranged in the semiconductor layer. The first conductive layer may include a second connection electrode 12 which serves as the first adapter electrode, the second conductive layer may include a fifth connection electrode 15 which serves as the second adapter electrode, and the fifth connection electrode 15 in the second conductive layer may be simultaneously connected to the second connection electrode 12 in the first conductive layer and the second active layer in the semiconductor layer through a second via V2 which serves as an adapter structure via.

In an exemplary implementation, the fourth transistor T4 at least includes a fourth active layer, and the fourth active layer is arranged in the semiconductor layer. The second conductive layer may include a sixth connection electrode 16 which serves as the second adapter electrode, and the sixth connection electrode 16 in the second conductive layer may be simultaneously connected to the data signal line 60 in the first conductive layer and the fourth active layer in the semiconductor layer through a third via V3 which serves as an adapter structure via.

In an exemplary implementation, the fifth transistor T5 at least includes a fifth active layer, and the fifth active layer is arranged in the semiconductor layer. The second conductive layer may include a seventh connection electrode 17 which serves as the second adapter electrode, and the seventh connection electrode 17 in the second conductive layer may be simultaneously connected to the first power supply line 70 in the first conductive layer and the fifth active layer in the semiconductor layer through a fourth via V4 which serves as an adapter structure via.

In an exemplary implementation, the sixth transistor T6 at least includes a sixth active layer, and the sixth active layer is arranged in the semiconductor layer. The third conductive layer may include an anode connection electrode 41 which serves as the third adapter electrode, and the anode connection electrode 41 in the third conductive layer may be connected to the sixth active layer in the semiconductor layer through a twelfth via V12 which serves as a single-hole structure via.

In an exemplary implementation, the seventh transistor T7 at least includes a seventh active layer, and the seventh active layer is arranged in the semiconductor layer. The second conductive layer may include an eighth connection electrode 18 which serves as the second adapter electrode, and the eighth connection electrode 18 in the second conductive layer may be simultaneously connected to the first power supply line 70 in the first conductive layer and the seventh active layer in the semiconductor layer through a fifth via V5 which serves as an adapter structure via.

In an exemplary implementation, at least one circuit unit may further include at least one power supply connection line 42 extending in the first direction X, and the power supply connection line 42 is connected to the first power supply line 70 to form a net-like connecting structure that transmits the first power supply signal.

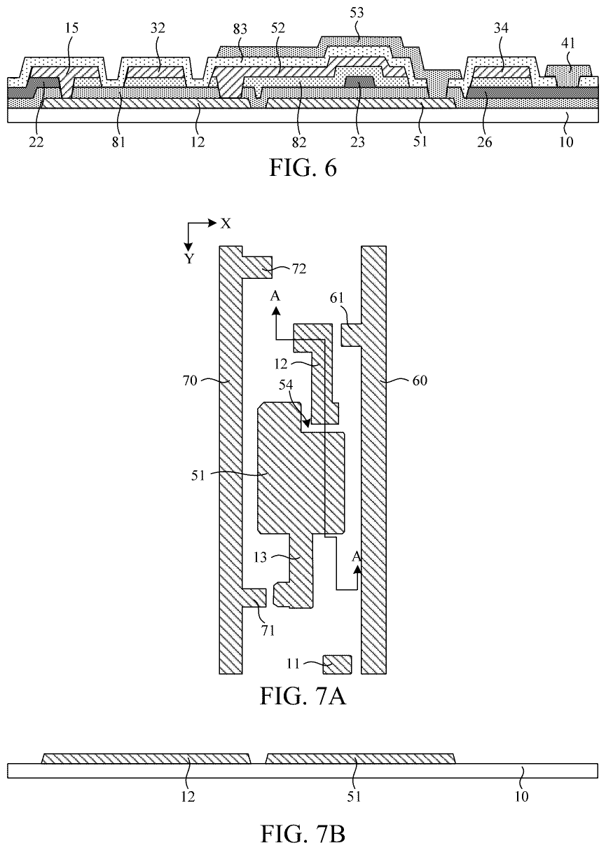

FIG. 6 is a sectional view taken in an A-A direction in FIG. 5. As shown in FIG. 6, the display substrate may include a first conductive layer arranged on the base substrate 10, a first insulating layer 81 arranged on a side of the first conductive layer away from the base substrate 10, a semiconductor layer arranged on a side of the first insulating layer 81 away from the base substrate 10, a second insulating layer 82 arranged on a side of the semiconductor layer away from the base substrate 10, a second conductive layer arranged on a side of the second insulating layer 82 away from the base substrate 10, a third insulating layer 83 arranged on a side of the second conductive layer away from the base substrate 10, and a third conductive layer arranged on a side of the third insulating layer 83 away from the base substrate 10.

In an exemplary implementation, the first conductive layer may at least include the second connection electrode 12 and the first electrode plate 51 of the storage capacitor, the semiconductor layer may at least include the second active layer 22, the third active layer 23 and the sixth active layer 26, the second conductive layer may at least include the fifth connection electrode 15, the second scan signal line 32, the light emitting signal line 34 and the second electrode plate 52 of the storage capacitor, and the third conductive layer may at least include the anode connection electrode 41 and the third electrode plate 53 of the storage capacitor.

In an exemplary implementation, the orthographic projection of the second electrode plate 52 on the base substrate at least partially overlaps with the orthographic projection of the first electrode plate 51 on the base substrate, the second electrode plate 52 and the first electrode plate 51 form a first capacitor of the storage capacitor, the orthographic projection of the third electrode plate 53 on the base substrate at least partially overlaps with the orthographic projection of the second electrode plate 52 on the base substrate, the second electrode plate 52 and the third electrode plate 53 form a second capacitor of the storage capacitor, the third electrode plate 53 is connected to the first electrode plate 51 through a via, and the first capacitor and the second capacitor connected in parallel form the storage capacitor of the pixel drive circuit.

In an exemplary implementation, the fifth connection electrode 15 in the second conductive layer may be simultaneously connected to the second connection electrode 12 in the first conductive layer and the second active layer 22 in the semiconductor layer through a second via which serves as an adapter structure via. In an exemplary implementation, the second connection electrode 12 is also connected to the second electrode plate 52 through a via.

In an exemplary implementation, the anode connection electrode 41 in the third conductive layer may be connected to the sixth active layer 26 in the semiconductor layer through the twelfth via which serves as a single-hole structure via

Exemplary description is made below through a preparation process of the display substrate according to the exemplary embodiment. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition; coating may be any one or more of spray coating, spin coating, and inkjet printing; and etching may be any one or more of dry etching and wet etching, which is not limited in present disclosure. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation, taking one circuit unit as an example, the manufacturing process of the display substrate in this embodiment may include the following operations.
(11) A pattern of a first conductive layer is formed. In an exemplary implementation, forming the pattern of the first conductive layer may include: depositing a first conductive thin film on a base substrate, and patterning the first conductive thin film by a patterning process to form the pattern of the first conductive layer on the base substrate, as shown in FIG. 7A. In an exemplary implementation, the first conductive layer may be referred to as a shield layer.

In an exemplary implementation, the first conductive layer of each circuit unit in the display substrate may at least include the first connection electrode 11, the second connection electrode 12, the third connection electrode 13, the first electrode plate 51 of the storage capacitor, the data signal line 60 and the first power supply line 70.

In an exemplary implementation, the first electrode plate 51 may be in a shape of a rectangle, corners of the rectangle may be chamfered, and the first electrode plate 51 may be arranged in a middle area of a circuit unit in the first direction X and the second direction Y. The first electrode plate 51 may serve as a lower electrode plate of the storage capacitor and also as a shield structure of the third transistor T3 to shield the channel region of the third transistor T3 to reduce the influence of light on the electrical characteristics of the third transistor T3 and stabilize the illumination characteristics of the oxide semiconductor.

In an exemplary implementation, a first opening 54 may be provided on a side of the first electrode plate 51 in an opposite direction of the second direction Y, the first opening 54 may be in a shape of a block (such as a rectangle), and the first opening 54 is configured to accommodate a second end of the second connection electrode 12.

In an exemplary implementation, the first connection electrode 11 may be in a shape of a block (such as a rectangle), and may be arranged on a side of the first electrode plate 51 in the second direction Y. In an exemplary implementation, the first connection electrode 11 may serve as one of the first adapter electrodes of the present disclosure and be configured to be connected to an initial signal line formed subsequently.

In an exemplary implementation, the second connection electrode 12 may be in a shape of a strip extending in the second direction Y and may be arranged on a side of the first electrode plate 51 in the opposite direction of the second direction Y, the first end of the second connection electrode 12 may be an end away from the first electrode plate 51, the second end of the second connection electrode 12 may be an end close to the first electrode plate 51, and the second end of the second connection electrode 12 may be arranged in the first opening 54 of the first electrode plate 51. In an exemplary implementation, the second connection electrode 12 may serve as one of the first adapter electrodes of the present disclosure, the first end of the second connection electrode 12 is configured to be connected to a fifth connection electrode formed subsequently, and the second end of the second connection electrode 12 is configured to be connected to a second electrode plate formed subsequently.

In an exemplary implementation, the third connection electrode 13 may be in a shape of a strip extending in the second direction Y and may be arranged on a side of the first electrode plate 51 in the second direction Y, the first end of the third connection electrode 13 is connected to the first electrode plate 51, and the second end of the third connection electrode 13 extends in a direction away from the first electrode plate 51. In an exemplary implementation, the third connection electrode 13 is configured to be connected to an anode connection electrode formed subsequently.

In an exemplary implementation, the third connection electrode 13 and the first electrode plate 51 may be connected to each other to form an integrated structure.

In an exemplary implementation, the data signal line 60 may be in a shape of a straight line or a polyline extending in the second direction Y and may be arranged on a side of the first electrode plate 51 in the first direction X.

In an exemplary implementation, a data connection block 61 may be arranged on the data signal line 60, the data connection block 61 may be in a shape of a block (such as a rectangle) and may be arranged on a side of the data signal line 60 close to the first electrode plate 51, the first end of the data connection block 61 is connected to the data signal line 60, and the second end of the data connection block 61 extends in a direction away from the data signal line 60. In an exemplary implementation, the data connection block 61 may serve as one of the first adapter electrodes of the present disclosure and is configured to be connected to a sixth connection electrode formed subsequently.

In an exemplary implementation, the data signal line 60 and the data connection block 61 may be connected to each other to form an integrated structure.

In an exemplary implementation, the first power supply line 70 may be in a shape of a straight line or a polyline extending in the second direction Y and may be arranged on a side of the first electrode plate 51 in the opposite direction of the first direction X, i.e., the data signal line 60 and the first power supply line 70 are arranged on the two sides of the first electrode plate 51 in the first direction X, respectively.

In an exemplary implementation, a first power supply connection block 71 may be arranged on the first power supply line 70, and the first power supply connection block 71 may be in a shape of a block (such as a rectangle) and may be arranged on a side of the first power supply line 70 close to the first electrode plate 51 and on a side of the first electrode plate 51 in the second direction Y. The first end of the first power supply connection block 71 is connected to the first power supply line 70, and the second end of the first power supply connection block 71 extends in a direction away from the first power supply line 70. In an exemplary implementation, the first power supply connection block 71 may serve as one of the first adapter electrodes of the present disclosure and is configured to be connected to a seventh connection electrode formed subsequently.

In an exemplary implementation, the first power supply line 70 and the first power supply connection block 71 may be connected to each other to form an integrated structure.

In an exemplary implementation, a second power supply connection block 72 may be arranged on the first power supply line 70, and the second power supply connection block 72 may be in a shape of a block (such as a rectangle) and may be arranged on a side of the first power supply line 70 close to the first electrode plate 51 and on a side of the first electrode plate 51 in the opposite direction of the second direction Y. The first end of the second power supply connection block 72 is connected to the first power supply line 70, and the second end of the second power supply connection block 72 extends in a direction away from the first power supply line 70. In an exemplary implementation, the second power supply connection block 72 may serve as one of the first adapter electrodes of the present disclosure and is configured to be connected to an eighth connection electrode formed subsequently.

In an exemplary implementation, the first power supply line 70 and the second power supply connection block 72 may be connected to each other to form an integrated structure.

In an exemplary implementation, the first power supply line 70, the first power supply connection block 71 and the second power supply connection block 72 may be connected to each other to form an integrated structure.

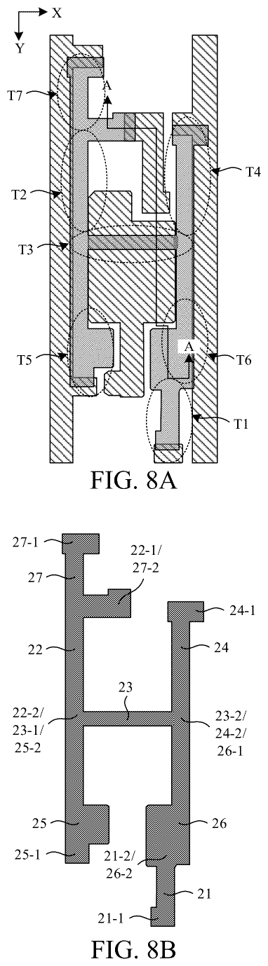

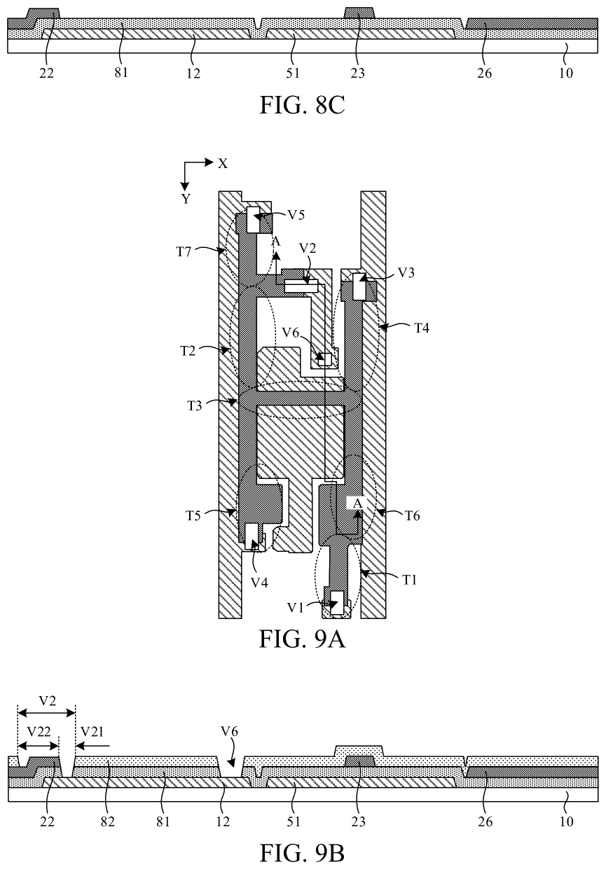

FIG. 7B is a sectional view taken in an A-A direction in FIG. 7A. As shown in FIG. 7B, the first conductive layer is arranged on the base substrate 10, and the first conductive layer may at least include the second connection electrode 12 and the first electrode plate 51 of the storage capacitor.
(12) A pattern of a semiconductor layer is formed. In an exemplary implementation, forming the pattern of the semiconductor layer may include: depositing sequentially a first insulating thin film and a semiconductor thin film on the base substrate on which the aforementioned pattern is formed, and patterning the semiconductor thin film through a patterning process to form a first insulating layer covering the first conductive layer and the pattern of the semiconductor layer arranged on the first insulating layer, as shown in FIG. 8A and FIG. 8B, FIG. 8B being a planar schematic diagram of the semiconductor layer in FIG. 8A.

In an exemplary implementation, the pattern of the semiconductor layer of each circuit unit in the display substrate may include the first active layer 21 of the first transistor T1 to the seventh active layer 27 of the seventh transistor T7, and the first active layer 21 to the seventh active layer 27 are connected to each another to form an integrated structure.

In an exemplary implementation, in the first direction X, the first active layer 21, the fourth active layer 24 and the sixth active layer 26 may be located on a side of the third active layer 23 in the first direction X, and the second active layer 22, the fifth active layer 25 and the seventh active layer 27 may be located on a side of the third active layer 23 in the opposite direction of the first direction X. In the second direction Y, the first active layer 21, the fifth active layer 25 and the sixth active layer 26 may be located on a side of the third active layer 23 in the second direction Y, and the second active layer 22, the fourth active layer 24 and the seventh active layer 27 may be located on a side of the third active layer 23 in the opposite direction of the second direction Y.

In an exemplary implementation, the third active layer 23 may be in a shape of a strip extending in the first direction X, and the first active layer 21, the second active layer 22, the fourth active layer 24, the fifth active layer 25, the sixth active layer 26 and the seventh active layer 27 may be in a shape of a strip extending in the second direction Y.

In an exemplary implementation, an active layer of each transistor may include a first region, a second region, and a channel region located between the first region and the second region. A second region 21-2 of the first active layer may serve as a second region 26-2 of the sixth active layer, i.e., the second region 21-2 of the first active layer and the second region 26-2 of the sixth active layer may be connected to each other. A first region 22-1 of the second active layer may serve as a second region 27-2 of the seventh active layer, i.e., the first region 22-1 of the second active layer and the second region 27-2 of the seventh active layer may be connected to each other. A second region 22-2 of the second active layer may also serve as a first region 23-1 of the third active layer and a second region 25-2 of the fifth active layer, i.e., the second region 22-2 of the second active layer, the first region 23-1 of the third active layer and the second region 25-2 of the fifth active layer may be connected to each other. A second region 23-2 of the third active layer may also serve as a second region 24-2 of the fourth active layer and a first region 26-1 of the sixth active layer, i.e., the second region 23-2 of the third active layer, the second region 24-2 of the fourth active layer and the first region 26-1 of the sixth active layer may be connected to each other. A first region 21-1 of the first active layer, a first region 24-1 of the fourth active layer, a first region 25-1 of the fifth active layer and a first region 27-1 of the seventh active layer may be arranged separately.

In an exemplary implementation, the orthographic projection of the third active layer 23 on the base substrate at least partially overlaps with the orthographic projection of the first electrode plate 51 on the base substrate, so that the first electrode plate 51 may shield the channel region of the third active layer 23 to reduce the influence of light on the electrical characteristics of the third transistor T3 and stabilize the illumination characteristics of the oxide semiconductor.

In an exemplary implementation, an orthographic projection of the first region 21-1 of the first active layer on the base substrate at least partially overlaps with an orthographic projection of the first connection electrode 11 on the base substrate, so that the initial signal line formed subsequently may be simultaneously connected to the first connection electrode 11 and the first region 21-1 of the first active layer.

In an exemplary implementation, an orthographic projection of the first region 22-1 of the second active layer (also the second region 27-2 of the seventh active layer) on the base substrate at least partially overlaps with an orthographic projection of the second connection electrode 12 on the base substrate, so that the fifth connection electrode formed subsequently may be simultaneously connected to the second connection electrode 12 and the first region 22-1 of the second active layer (also the second region 27-2 of the seventh active layer).

In an exemplary implementation, an orthographic projection of the first region 24-1 of the fourth active layer on the base substrate at least partially overlaps with an orthographic projection of the data connection block 61 on the base substrate, so that the sixth connection electrode formed subsequently may be simultaneously connected to the data connection block 61 and the first region 24-1 of the fourth active layer.

In an exemplary implementation, an orthographic projection of the first region 25-1 of the fifth active layer on the base substrate at least partially overlaps with an orthographic projection of the first power supply connection block 71 on the base substrate, so that the seventh connection electrode formed subsequently may be simultaneously connected to the first power supply connection block 71 and the first region 25-1 of the fifth active layer.

In an exemplary implementation, an orthographic projection of the first region 27-1 of the seventh active layer on the base substrate at least partially overlaps with an orthographic projection of the second power supply connection block 72 on the base substrate, so that an eighth connection electrode formed subsequently may be simultaneously connected to the second power supply connection block 72 and the first region 27-1 of the seventh active layer.

In an exemplary implementation, the semiconductor layer may be made of an oxide, i.e., the first transistor T1 to the seventh transistor T7 are oxide transistors. Oxide transistors have advantages of high electron mobility, low working voltage, low leakage characteristics, etc. In an exemplary implementation, the oxide may be any one or more of following: Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAlO), Strontium Copper Oxide (SrCuO), Lanthanum Copper Oxysulfide (LaCuOS), Gallium Nitride (GaN), Indium Gallium Nitride (InGaN), Aluminum Gallium Nitride (AlGaN), and Indium Gallium Aluminum Nitride (InGaAIN). In an exemplary implementation, the semiconductor layer may be made of Indium Gallium Zinc Oxide (IGZO), wherein electron mobility of the Indium Gallium Zinc Oxide (IGZO) is higher than that of amorphous silicon.

In another exemplary implementation, the semiconductor layer may be made of polysilicon, i.e., the first transistor to the seventh transistor T7 may be polysilicon transistors.

FIG. 8C is a sectional view taken in an A-A direction in FIG. 8A. As shown in FIG. 8C, the first conductive layer is arranged on the base substrate 10, the first insulating layer 81 is arranged on a side of the first conductive layer away from the base substrate 10, the semiconductor layer is arranged on a side of the first insulating layer 81 away from the base substrate 10, the semiconductor layer may at least include the second active layer 22, the third active layer 23 and the sixth active layer 26, the orthographic projection of the second active layer 22 on the base substrate at least partially overlaps with the orthographic projection of the second connection electrode 12 on the base substrate, and the orthographic projection of the third active layer 23 on the base substrate at least partially overlaps with the orthographic projection of the first electrode plate 51 on the base substrate. The first electrode plate 51 which serves as a shield structure may shield the channel region of the third active layer 23 to reduce the influence of light on the electrical characteristics of the third transistor T3 and stabilize the illumination characteristics of the oxide semiconductor.
(13) A pattern of a second insulating layer is formed. In an exemplary implementation, forming the pattern of the second insulating layer may include: depositing a second insulating thin film on the base substrate on which the aforementioned patterns are formed, and patterning the second insulating thin film through a patterning process to form the second insulating layer covering the semiconductor layer, a plurality of vias being provided on the second insulating layer, as shown in FIG. 9A.

In an exemplary implementation, a plurality of vias of each circuit unit in the display substrate at least include: a first via V1, a second via V2, a third via V3, a fourth via V4, a fifth via V5 and a sixth via V6.

In an exemplary implementation, an orthographic projection of the first via V1 on the base substrate at least partially overlaps with the orthographic projections of the first connection electrode 11 and the first region 21-1 of the first active layer on the base substrate. The first via V1 may be an adapter structure via, including a deep half hole and a shallow half hole. The second insulating layer and the first insulating layer in the deep half hole are etched away to expose the surface of the first connection electrode 11, and the second insulating layer in the shallow half hole is etched away to expose the surface of the first region 21-1 of the first active layer. The first via V1 serves as one of the adapter structure vias in the present disclosure and is configured so that the initial signal line formed subsequently is simultaneously connected to the first connection electrode 11 and the first region 21-1 of the first active layer through this via.

In an exemplary implementation, an orthographic projection of the second via V2 on the base substrate at least partially overlaps with the orthographic projections of the first end of the second connection electrode 12 away from the first electrode plate 51 and the first region 22-1 of the second active layer (also the second region 27-2 of the seventh active layer) on the base substrate. The second via V2 may be an adapter structure via, including a deep half hole and a shallow half hole. The second insulating layer and the first insulating layer in the deep half hole are etched away to expose the surface of the first end of the second connection electrode 12, and the second insulating layer in the shallow half hole is etched away to expose the surface of the first region 22-1 of the second active layer (also the second region 27-2 of the seventh active layer). The second via V2 serves as one of the adapter structure vias in the present disclosure and is configured so that the fifth connection electrode formed subsequently is simultaneously connected to the first end of the second connection electrode 12 and the first region 22-1 of the second active layer (also the second region 27-2 of the seventh active layer) through this via.

In an exemplary implementation, an orthographic projection of the third via V3 on the base substrate at least partially overlaps with the orthographic projections of the data connection block 61 and the first region 24-1 of the fourth active layer on the base substrate. The third via V3 may be an adapter structure via, including a deep half hole and a shallow half hole. The second insulating layer and the first insulating layer in the deep half hole are etched away to expose the surface of the data connection block 61, and the second insulating layer in the shallow half hole is etched away to expose the surface of the first region 24-1 of the fourth active layer. The third via V3 serves as one of the adapter structure vias in the present disclosure and is configured so that the sixth connection electrode formed subsequently is simultaneously connected to the data connection block 61 and the first region 24-1 of the fourth active layer through this via.

In an exemplary implementation, an orthographic projection of the fourth via V4 on the base substrate at least partially overlaps with the orthographic projections of the first power supply connection block 71 and the first region 25-1 of the fifth active layer on the base substrate. The fourth via V4 may be an adapter structure via, including a deep half hole and a shallow half hole. The second insulating layer and the first insulating layer in the deep half hole are etched away to expose the surface of the first power supply connection block 71, and the second insulating layer in the shallow half hole is etched away to expose the surface of the first region 25-1 of the fifth active layer. The fourth via V4 serves as one of the adapter structure vias in the present disclosure and is configured so that the seventh connection electrode formed subsequently is simultaneously connected to the first power supply connection block 71 and the first region 25-1 of the fifth active layer through this via.

In an exemplary implementation, an orthographic projection of the fifth via V5 on the base substrate at least partially overlaps with the orthographic projections of the second power supply connection block 72 and the first region 27-1 of the seventh active layer on the base substrate. The fifth via V5 may be an adapter structure via, including a deep half hole and a shallow half hole. The second insulating layer and the first insulating layer in the deep half hole are etched away to expose the surface of the second power supply connection block 72, and the second insulating layer in the shallow half hole is etched away to expose the surface of the first region 27-1 of the seventh active layer. The fifth via V5 serves as one of the adapter structure vias in the present disclosure and is configured so that the eighth connection electrode formed subsequently is simultaneously connected to the second power supply connection block 72 and the first region 27-1 of the seventh active layer through this via.

In an exemplary implementation, an orthographic projection of the sixth via V6 on the base substrate is located within the range of the orthographic projection of the second end of the second connection electrode 12 close to the first electrode plate 51 on the base substrate. The sixth via V6 is a single-hole structure via. The second insulating layer and the first insulating layer in the sixth via V6 are etched away to expose the surface of the second end of the second connection electrode 12. The sixth via V6 is configured so that the second electrode plate formed subsequently is connected to the second end of the second connection electrode 12 through this via.

In an exemplary implementation mode, in a process of forming a pattern of a second insulating layer, a plurality of vias are formed using a dry etching process while a first conductorization process is performed on a semiconductor layer exposed in the vias. In the first conductorization process, edge portions of the semiconductor layer covered by the second insulating layer close to the vias are also conductorized, that is, the semiconductor layer after the first conductorization process extends in a direction away from the vias to form a first conductorized region.

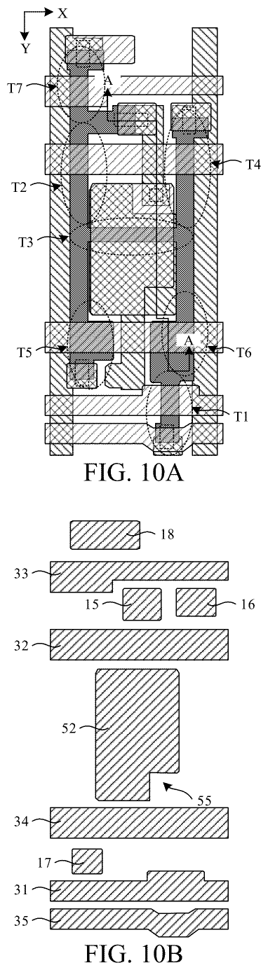

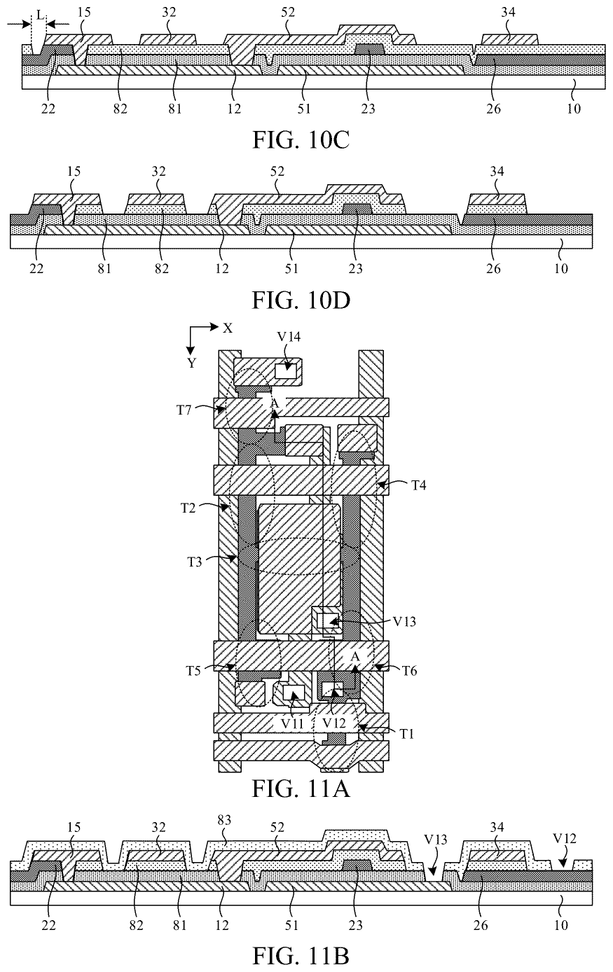

FIG. 9B is a sectional view taken in an A-A direction in FIG. 9A. As shown in FIG. 9B, the first conductive layer is arranged on the base substrate 10, the first insulating layer 81 is arranged on a side of the first conductive layer away from the base substrate 10, the semiconductor layer is arranged on a side of the first insulating layer 81 away from the base substrate 10, the second insulating layer 82 is arranged on a side of the semiconductor layer away from the base substrate 10, and the second insulating layer 82 is at least provided with the second via V2 and the sixth via V6. The second via V2 is an adapter structure via and includes a deep half hole V21 and a shallow half hole V22. The second insulating layer 82 and the first insulating layer 81 in the deep half hole V21 are etched away to expose the surface of the first end of the second connection electrode 12, and the second insulating layer 82 in the shallow half hole V22 is etched away to expose the surface of the second active layer 22. The sixth via V6 is a single-hole structure via, and the second insulating layer 82 and the first insulating layer 81 in the sixth via V6 are etched away to expose the surface of the second end of the second connection electrode 12.
(14) A pattern of a second conductive layer is formed. In an exemplary implementation, forming the pattern of the second conductive layer may include: depositing a second conductive thin film on the base substrate on which the aforementioned patterns are formed, and patterning the second conductive thin film through a patterning process to form the pattern of the second conductive layer arranged on the second insulating layer, as shown in FIGS. 10A and 10B, FIG. 10B being a schematic diagram of the second conductive layer in FIG. 10A. In an exemplary implementation, the second conductive layer may be referred to as a gate metal (GATE) layer.

In an exemplary implementation, the pattern of the second conductive layer of each circuit unit in the display substrate at least includes: a fifth connection electrode 15, a sixth connection electrode 16, a seventh connection electrode 17, an eighth connection electrode 18, a first scan signal line 31, a second scan signal line 32, a third scan signal line 33, a light emitting signal line 34, an initial signal line 35, and a second electrode plate 52 of a storage capacitor.

In an exemplary implementation, the first scan signal line 31, the second scan signal line 32, the third scan signal line 33, the light emitting signal line 34 and the initial signal line 35 may be in a shape of a straight line or a polyline extending in the first direction X. The light emitting signal line 34 may be located on a side of the first electrode plate 51 in the second direction Y, the first scan signal line 31 may be located on a side of the light emitting signal line 34 away from the first electrode plate 51, the initial signal line 35 may be located on a side of the first scan signal line 31 away from the first electrode plate 51, the second scan signal line 32 may be located on a side of the first electrode plate 51 in the opposite direction of the second direction Y, and the third scan signal line 33 may be located on a side of the second scan signal line 32 away from the first electrode plate 51.

In an exemplary implementation, an orthographic projection of the first scan signal line 31 on the base substrate at least partially overlaps with the orthographic projection of the first active layer on the base substrate, and the overlapping area may serve as the gate electrode of the first transistor T1, so that the first scan signal line 31 can control turn-on or turn-off of the first transistor T1.

In an exemplary implementation, an orthographic projection of the second scan signal line 32 on the base substrate at least partially overlaps with the orthographic projections of the second active layer and the fourth active layer on the base substrate, the area overlapping with the second active layer may serve as the gate electrode of the second transistor T2, and the area overlapping with the fourth active layer may serve as the gate electrode of the fourth transistor T4, so that the second scan signal line 32 can simultaneously control turn-on or turn-off of the second transistor T2 and the fourth transistor T4.

In an exemplary implementation, an orthographic projection of the third scan signal line 33 on the base substrate at least partially overlaps with the orthographic projection of the seventh active layer on the base substrate, and the overlapping area may serve as the gate electrode of the seventh transistor T7, so that the third scan signal line 33 can control turn-on or turn-off of the seventh transistor T7.

In an exemplary implementation, the first scan signal line 31 and the third scan signal line 33 may be connected to a same signal line, i.e., the first scan signal line 31 and the third scan signal line 33 may synchronously control turn-on or turn-off of the first transistor T1 and the seventh transistor T7.

In an exemplary implementation, an orthographic projection of the light emitting signal line 34 on the base substrate at least partially overlaps with the orthographic projections of the fifth active layer and the sixth active layer on the base substrate, the area overlapping with the fifth active layer may serve as the gate electrode of the fifth transistor T5, and the area overlapping with the sixth active layer may serve as the gate electrode of the sixth transistor T6, so that the light emitting signal line 34 can simultaneously control turn-on or turn-off of the fifth transistor T5 and the sixth transistor T6.

In an exemplary implementation, the initial signal line 35 may be simultaneously connected to the first connection electrode 11 and the first region 21-1 of the first active layer through the first via V1 which serves as an adapter structure via, thus enabling the initial signal line 35 to write an initial signal to the first electrode of the first transistor T1.

In an exemplary implementation, the fifth connection electrode 15 may be in a shape of a block (such as a rectangle) and may be arranged between the second scan signal line 32 and the third scan signal line 33, and the fifth connection electrode 15 is simultaneously connected to the first end of the second connection electrode 12 and the first region of the second active layer (also the second region of the seventh active layer) through the second via V2 which serves as an adapter structure via. In an exemplary implementation, the fifth connection electrode 15 may serve as one of the second adapter electrodes in the present disclosure.

In an exemplary implementation, the sixth connection electrode 16 may be in a shape of a block (such as a rectangle) and may be arranged between the second scan signal line 32 and the third scan signal line 33, and the sixth connection electrode 16 is simultaneously connected to the data connection block 61 and the first region of the fourth active layer through the third via V3 which serves as an adapter structure via. Since the data connection block 61 is connected to the data signal line 60, it is realized that the data signal line 60 writes a data signal to the first electrode of the fourth transistor T4. In an exemplary implementation, the sixth connection electrode 16 may serve as one of the second adapter electrodes in the present disclosure.

In an exemplary implementation, the seventh connection electrode 17 may be in a shape of a block (such as a rectangle) and may be arranged between the first scan signal line 31 and the light emitting signal line 34, and the seventh connection electrode 17 is simultaneously connected to the first power supply connection block 71 and the first region of the fifth active layer through the fourth via V4 which serves as an adapter structure via. Since the first power supply connection block 71 is connected to the first power supply line 70, it is realized that the first power supply line 70 writes a first power supply signal to the first electrode of the fifth transistor T5. In an exemplary implementation, the seventh connection electrode 17 may serve as one of the second adapter electrodes in the present disclosure.

In an exemplary implementation, the eighth connection electrode 18 may be in a shape of a block (such as a rectangle) and may be arranged on a side of the third scan signal line 33 away from the first electrode plate 51, and the eighth connection electrode 18 is simultaneously connected to the second power supply connection block 72 and the first region of the seventh active layer through the fifth via V5 which serves as an adapter structure via. Since the second power supply connection block 72 is connected to the first power supply line 70, it is realized that the first power supply line 70 writes a first power supply signal to the first electrode of the seventh transistor T7. In an exemplary implementation, the eighth connection electrode 18 may serve as one of the second adapter electrodes in the present disclosure.

In an exemplary implementation, the second electrode plate 52 may be in a shape of a rectangle whose corners may be chamfered, and may be arranged between the second scan signal line 32 and the light emitting signal line 34, the orthographic projection of the second electrode plate 52 on the base substrate at least partially overlaps with the orthographic projection of the first electrode plate 51 on the base substrate, and the second electrode plate 52 is connected to the second end of the second connection electrode 12 through the sixth via V6.

In an exemplary implementation, the orthographic projection of the second electrode plate 52 on the base substrate at least partially overlaps with the orthographic projection of the third active layer on the base substrate, and the second electrode plate 52 may serve as the gate electrode of the third transistor T3. The orthographic projection of the second electrode plate 52 on the base substrate at least partially overlaps with the orthographic projection of the first electrode plate 51 on the base substrate. The second electrode plate 52 may serve as an intermediate electrode plate of the storage capacitor, and the first electrode plate 51 and the second electrode plate 52 may form a first capacitor of the storage capacitor. Since the second connection electrode 12 is connected to the first region of the second active layer (also the second region of the seventh active layer) through the fifth connection electrode 15, the first electrode of the second transistor T2, the second electrode of the seventh transistor T7, and the second electrode plate 52 have the same potential, forming a first node N1 of a pixel drive circuit.

In an exemplary implementation, an edge on a side of the second electrode plate 52 close to the light emitting signal line 34 may be provided with a second opening 55, the second opening 55 may be in a shape of a block (such as a rectangle) and may be arranged on a side close to the data signal line 60, an orthographic projection of the second opening 55 on the base substrate at least partially overlaps with the orthographic projection of the first electrode plate 51 on the base substrate, and the second opening 55 is configured to accommodate the thirteenth via formed subsequently.

In an exemplary implementation, the structures such as the data signal line and the first power supply line are arranged in the first conductive layer, the active layers of the plurality of transistors are arranged in the semiconductor layer, the structures such as the gate electrodes of the plurality of transistors and the plurality of connection electrodes are arranged in the second conductive layer, and the plurality of connection electrodes located in the second conductive layer realize connection between the semiconductor layer and the first conductive layer. Therefore, the first transistor T1, the second transistor T2, the fourth transistor T4, the fifth transistor T5 and the seventh transistor T7 are transistors of a Top Gate bottom connect (TGBC) structure.

FIGS. 10C and 10D are sectional views taken in an A-A direction in FIG. 10A. The first conductive layer is arranged on the base substrate 10, the first insulating layer 81 is arranged on a side of the first conductive layer away from the base substrate 10, the semiconductor layer is arranged on a side of the first insulating layer 81 away from the base substrate 10, the second insulating layer 82 is arranged on a side of the semiconductor layer away from the base substrate 10, the second conductive layer is arranged on a side of the second insulating layer 82 away from the base substrate 10, and the second conductive layer may at least include the fifth connection electrode 15, the second scan signal line 32, the light emitting signal line 34, and the second electrode plate 52 of the storage capacitor. The fifth connection electrode 15 may be simultaneously connected to the first end of the second connection electrode 12 and the second active layer 22 through the second via which serves as an adapter structure via, the orthographic projection of the second electrode plate 52 on the base substrate at least partially overlaps with the orthographic projection of the first electrode plate 51 on the base substrate, and the second electrode plate 52 is connected to the second end of the second connection electrode 12 through the sixth via V6.

In an exemplary implementation, in the process of forming the pattern of the second conductive layer, a wet etching process is employed first to form the pattern of the second conductive layer, achieving that the fifth connection electrode 15 is simultaneously connected to the second connection electrode 12 and the second active layer 22 through an adapter structure via, and the second electrode plate 52 is connected to the second connection electrode 12 through a single-hole structure via. In an exemplary implementation, a first distance L is arranged between an edge of the fifth connection electrode 15 located in a region of a shallow half hole and an edge of the shallow half hole, i.e., the fifth connection electrode 15 does not fully cover the shallow half hole, as shown in FIG. 10C.

In an exemplary implementation, after the pattern of the second conductive layer is formed through the wet etching process, a self-alignment process using the second conductive layer as a mask is used, the second insulating layer 82 in a region other than the second conductive layer is etched using a dry etching process to etch away the second insulating layer 82 in a region other than the second conductive layer, and at the same time, a second conductorization is performed on the exposed semiconductor layer, as shown in FIG. 10D. During the second conductorization process, an edge portion of the semiconductor layer covered by the second conductive layer is also conductorized, i.e., the semiconductor layer which has undergone the second conductorization process will extend to the region which has undergone the first conductorization process, to form a region conductorized twice in an area where the region which has undergone the first conductorization process overlaps with the region which has undergone the second conductorization process. This may ensure reliable connection between the second conductive layer and the semiconductor layer.
(15) A pattern of a third insulating layer is formed. In an exemplary implementation, forming the pattern of the third insulating layer may include: depositing a third insulating thin film on the base substrate on which the aforementioned patterns are formed, and patterning the third insulating thin film through a patterning process to form the third insulating layer covering the pattern of the second conductive layer, the third insulating layer being provided with a plurality of vias, as shown in FIG. 11A.

In an exemplary implementation, the plurality of vias in each circuit unit of the display substrate at least include: an eleventh via V11, a twelfth via V12, a thirteenth via V13, and a fourteenth via V14.

In an exemplary implementation, an orthographic projection of the eleventh via V11 on the base substrate is located within the range of the orthographic projection of the third connection electrode 13 on the base substrate, the third insulating layer and the first insulating layer in the eleventh via V11 are etched away to expose the surface of the third connection electrode 13, and the eleventh via V11 is configured such that the anode connection electrode formed subsequently is connected to the third connection electrode 13 through this via.

In an exemplary implementation, an orthographic projection of the twelfth via V12 on the base substrate is located within the range of the orthographic projection of the second region 26-2 of the sixth active layer (also the second region 21-2 of the first active layer) on the base substrate, the third insulating layer in the twelfth via V12 is etched away to expose the surface of the second region 26-2 of the sixth active layer (also the second region 21-2 of the first active layer), and the twelfth via V12 may serve as a single-hole structure via in the present disclosure and is configured such that the anode connection electrode formed subsequently is connected to the second region 26-2 of the sixth active layer (also the second region 21-2 of the first active layer) through this via.

In an exemplary implementation, an orthographic projection of the thirteenth via V13 on the base substrate is located within the range of the orthographic projection of the second opening 55 on the second electrode plate 52 on the base substrate, the third insulating layer and the first insulating layer in the thirteenth via V13 are etched away to expose the surface of the first electrode plate 51, and the thirteenth via V13 is configured such that the third electrode plate formed subsequently is connected to the first electrode plate 51 through this via.

In an exemplary implementation, an orthographic projection of the fourteenth via V14 on the base substrate is located within the range of the orthographic projection of the eighth connection electrode 18 on the base substrate, the third insulating layer in the fourteenth via V14 is etched away to expose the surface of the eighth connection electrode 18, and the fourteenth via V14 is configured such that the power supply connection line formed subsequently is connected to the eighth connection electrode 18 through this via.

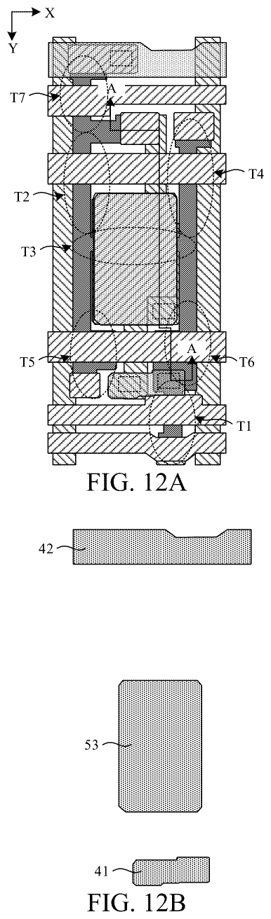

FIG. 11B is a sectional view taken in an A-A direction in FIG. 11A. As shown in FIG. 11B, the first conductive layer is arranged on the base substrate 10, the first insulating layer 81 is arranged on a side of the first conductive layer away from the base substrate 10, the semiconductor layer is arranged on a side of the first insulating layer 81 away from the base substrate 10, the second insulating layer 82 is arranged on a side of the semiconductor layer away from the base substrate 10, the second conductive layer is arranged on a side of the second insulating layer 82 away from the base substrate 10, and the third insulating layer 83 is arranged on a side of the second conductive layer away from the base substrate 10 and is at least provided with a twelfth via V12 and a thirteenth via V13, the twelfth via V12 exposing the surface of the sixth active layer 26, and the thirteenth via V13 exposing the surface of the first electrode plate 51.
(16) A pattern of a third conductive layer is formed. In an exemplary implementation, forming the third conductive layer may include: depositing a third conductive thin film on the base substrate on which the aforementioned patterns are formed, and patterning the third conductive thin film through a patterning process to form the third conductive layer arranged on the third insulating layer, as shown in FIG. 12A and FIG. 12B, FIG. 12B being a planar schematic diagram of the third conductive layer in FIG. 12A. In an exemplary implementation, the third conductive layer may be referred to as a source-drain metal (SD) layer.

In an exemplary implementation, the third conductive layer of each circuit unit in the display substrate at least includes: an anode connection electrode 41, a power supply connection line 42, and a third electrode plate 53 of the storage capacitor.

In an exemplary implementation, the anode connection electrode 41 may be in a shape of a strip extending in the first direction X, a first end of the anode connection electrode 41 is connected to the third connection electrode 13 through the eleventh via V11, and a second end of the anode connection electrode 41 is connected to the second region 26-2 of the sixth active layer (also the second region 21-2 of the first active layer) through the twelfth via V12. Since the third connection electrode 13 is connected to the first electrode plate 51, the anode connection electrode 41 enables the second electrode of the first transistor T1, the second electrode of the sixth transistor T6, and the first electrode plate 51 to have the same potential, forming a fourth node N4 of a pixel drive circuit.

In an exemplary implementation, the power supply connection line 42 may be in a shape of a straight line or a polyline extending in the first direction X and may be arranged on a side of the third scan signal line 33 away from the second electrode plate 52, and the power supply connection line 42 is connected to the eighth connection electrode 18 through the fourteenth via V14. Because the eighth connection electrode 18 is connected to the second power supply connection block 72 and the second power supply connection block 72 is connected to the first power supply line 70, interconnection between the power supply connection line 42 whose main body portion extends in the first direction X and the first power supply line 70 whose main body portion extends in the second direction Y is realized, and the power supply connection line 42 and the first power supply line 70 form a net-like connecting structure that transmits a first power supply signal on the display substrate, which may not only effectively reduce the resistance of the first power supply line and reduce the voltage drop of the first power supply signal, but also effectively improve uniformity of the first power supply signal in the display substrate and effectively improve display uniformity, thus improving the display quality.

In an exemplary implementation, the third electrode plate 53 may be in a shape of a rectangle whose corners may be chamfered, and may be arranged between the second scan signal line 32 and the light emitting signal line 34, and the third electrode plate 53 is connected to the first electrode plate 51 through the thirteenth via V13. In an exemplary implementation, an orthographic projection of the third electrode plate 53 on the base substrate at least partially overlaps with the orthographic projection of the second electrode plate 52 on the base substrate, the third electrode plate 53 may serve as an upper electrode plate of the storage capacitor, and the third electrode plate 53 and the second electrode plate 52 may form a second capacitor of the storage capacitor.

In an exemplary implementation, since the first electrode plate 51 has the potential of the fourth node N4 in the pixel drive circuit and the third electrode plate 53 is connected to the first electrode plate 51 through a via, the third electrode plate 53 also has the potential of the fourth node N4 in the pixel drive circuit. Since the second electrode plate 52 has the potential of the first node N1 in the pixel drive circuit, the second electrode plate 52 having the potential of the first node N1 and the first electrode plate 51 having the potential of the fourth node N4 form a first capacitor of the storage capacitor, the second electrode plate 52 having the potential of the first node N1 and the third electrode plate 53 having the potential of the fourth node N4 form a second capacitor of the storage capacitor, and the first capacitor and the second capacitor connected in parallel constitute the storage capacitor of the pixel drive circuit.

In an exemplary implementation, the active layers of the plurality of transistors are arranged in the semiconductor layer, the gate electrodes of the plurality of transistors are arranged in the second conductive layer, the structures such as the anode connection electrode are arranged in the third conductive layer, and the anode connection electrode located in the third conductive layer is connected to the semiconductor layer. Therefore, the sixth transistor T6 is a transistor of a Top Gate structure.

In an exemplary implementation, the first conductive layer is arranged on the base substrate 10, the first insulating layer 81 is arranged on a side of the first conductive layer away from the base substrate 10, the semiconductor layer is arranged on a side of the first insulating layer 81 away from the base substrate 10, the second insulating layer 82 is arranged on a side of the semiconductor layer away from the base substrate 10, the second conductive layer is arranged on a side of the second insulating layer 82 away from the base substrate 10, the third insulating layer 83 is arranged on a side of the second conductive layer away from the base substrate 10, the third conductive layer is arranged on a side of the third insulating layer 83 away from the base substrate 10, and the third conductive layer may at least include an anode connection electrode 41 and a third electrode plate 53, the anode connection electrode 41 is connected to the sixth active layer 26 through the twelfth via V12, and the third electrode plate 53 is connected to the first electrode plate 51 through the thirteenth via V13, as shown in FIG. 6.
(17) A pattern of a planarization layer is formed. In an exemplary implementation, forming the pattern of the planarization layer may include: coating a planarization thin film on the base substrate on which the aforementioned patterns are formed, and patterning the planarization thin film through a patterning process to form the planarization layer covering the pattern of the third conductive layer. The planarization layer in each circuit unit is at least provided with an anode via. An orthographic projection of the anode via on the base substrate is located within the range of the orthographic projection of the anode connection electrode on the base substrate, the planarization layer in the anode via is removed to expose the surface of the anode connection electrode, and the anode via is configured such that the anode formed subsequently is connected to the anode connection electrode through this via.

So far, a drive circuit layer has been prepared on the base substrate. In a plane parallel to the display substrate, the drive circuit layer may include a plurality of circuit units. Each of the circuit units may include a pixel drive circuit, and a first scan signal line, a second scan signal line, a third scan signal line, a light emitting signal line, an initial signal line, a data signal line and a first power supply line that are connected to the pixel drive circuit. In a plane perpendicular to the display substrate, the drive circuit layer may include a first conductive layer, a first insulating layer, a semiconductor layer, a second insulating layer, a second conductive layer, a third insulating layer, a third conductive layer and a planarization layer that are sequentially arranged on the base substrate. The first conductive layer may at least include a first electrode plate, a data signal line and a first power supply line. The semiconductor layer may at least include active layers of a plurality of transistors. The second conductive layer may at least include a second electrode plate, a first scan signal line, a second scan signal line, a third scan signal line, a light emitting signal line and an initial signal line. The third conductive layer may at least include a third electrode plate, an anode connection electrode and a power supply connection line.

In an exemplary implementation mode, the base substrate may be a flexible base substrate, or a rigid base substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible base substrate may include a first flexible material layer, a first inorganic material layer, a semiconductor layer, a second flexible material layer and a second inorganic material layer stacked on the glass carrier plate. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si).

In an exemplary implementation, the first insulating layer, the second insulating layer, and the third insulating layer may be made of any one or more of Silicon Oxide (SiOx), Silicon Nitride (SiNx), and Silicon Oxynitride (SiON), and may be a single layer, a multi-layer, or a composite layer. The first conductive layer, the second conductive layer and the third conductive layer may be made of a metal material such as silver (Ag), copper (Cu), aluminum (A1), titanium (Ti), molybdenum (Mo), etc., or may be made of an alloy material composed of metals, such as an aluminum-neodymium alloy (AlNd) or a molybdenum-niobium alloy (MoNb), etc., and may be of a single-layer structure or a multi-layer composite structure, such as Ti/A1/Ti or the like. The planarization layer may be made of an organic material, such as a resin or polyimide.

In an exemplary implementation, after the drive circuit layer is manufactured, a light emitting structure layer and an encapsulation structure layer may be sequentially manufactured on the drive circuit layer, which is not repeated here.

In a display substrate with a top gate bottom connect (TGBC) structure, a connection electrode located in a second conductive layer realizes the connection between a semiconductor layer and a first conductive layer through an adapter structure via. The inventors of the present application have found through research that the adapter structure via includes a deep half hole and a shallow half hole and needs to overlap with a first conductive layer, a semiconductor layer and a second conductive layer at the same time, as a consequence, the adapter structure via has a large area; moreover, considering the exposure alignment accuracy, etching deviation and non-uniformity due to etching, additional edge wrapping in a large size is further required for the outer side of each adapter structure via, which causes the pixel drive circuit to occupy a large area, limiting the improvement in display resolution of the display substrate. In addition, the complexity of the process of the adapter structure via affects the product yield.

An embodiment of the present disclosure provides a display substrate in which a TGBC structure is combined with a Top Gate structure, which not only can reduce the occupied area of a pixel drive circuit, facilitating improving display resolution, but also reduces the complexity of a punching process, facilitating improving product yield. In the display substrate according to an embodiment of the present disclosure, the first transistor T1 connected to the initial signal line, the second transistor T2 connected to the second electrode plate, the fourth transistor T4 connected to the data signal line, and the fifth transistor T5 and the seventh transistor T7 connected to the first power supply line have a TGBC structure, and the sixth transistor T6 connected to the anode connection electrode has a Top Gate structure. Compared with a display substrate in which all transistors have a TGBC structure, in the display substrate of the present disclosure, the number of adapter structure vias is reduced from 6 to 5, which can effectively reduce the occupied area of the pixel drive circuit, effectively improving display resolution. In addition, reducing the number of adapter structure vias may lead to a reduction in the complexity of the punching process, which may reduce the production cost and effectively improve the product yield. Compared with a display substrate in which all transistors have a Top Gate structure, in the display substrate of the present disclosure, the data signal line and the first power supply line are arranged in the first conductive layer, which not only can reduce the coupling capacitance between the data signal line and the first power supply line and other signals, reducing crosstalk between signals, but also can effectively reduce the delay time RC of the data signal line, effectively reducing logic power consumption.

In an embodiment of the present disclosure, the first conductive layer, the second conductive layer and the third conductive layer form a sandwich structure with a three-layer metal layout, and the first capacitor and the second capacitor in a parallel structure constitute the storage capacitor, which, on the one hand, can effectively increase the capacitance value of the storage capacitor, and on the other hand, can reduce the area of the electrode plates while ensuring the capacitance value of the storage capacitor, thereby further reducing the occupied area of the pixel drive circuit and effectively improving the display resolution.

In an embodiment of the present disclosure, a power supply connection line whose main body portion extends in the first direction X and a first power supply line whose main body portion extends in the second direction Y are arranged, and the first power supply line and the power supply connection line are connected to each other, so that the first power supply line and the power supply connection line form a net-like structure that transmits a first power supply signal on the display substrate, which can not only effectively reduce the resistance of the first power supply line and reduce the voltage drop of the first power supply signal, but also effectively improve the uniformity of the first power supply signal in the display substrate and effectively improve the display uniformity, thus improving the display quality.

In an exemplary implementation, by arranging the scan signal line and the light emitting signal line in the source-drain metal (SD) layer, the present disclosure effectively reduces the resistance of the scan signal line and the light emitting signal line, reduces the voltage drop of the scan signal line and the light emitting signal line, and effectively improves the compensation speed.

The preparation process in the present disclosure may be compatible well with an existing preparation process, is simple in process implementation, is easy to implement, and has a high production efficiency, a low production cost, and a high yield.

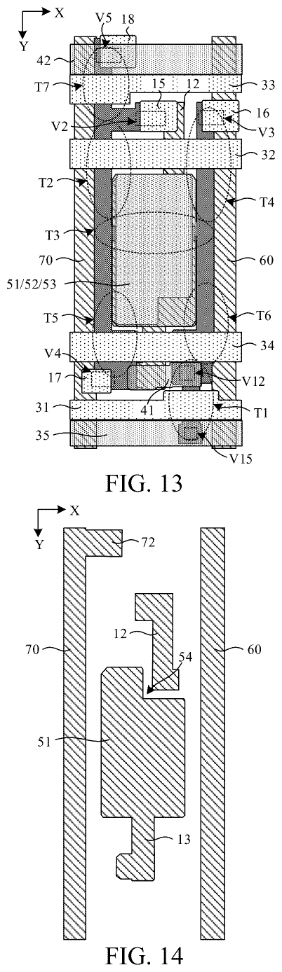

FIG. 13 is a schematic diagram of a planar structure of another display substrate according to an exemplary embodiment of the present disclosure, illustrating a structure of one circuit unit. As shown in FIG. 13, in an exemplary implementation, the main body structure of the display substrate of this embodiment is substantially the same as the structure of the embodiment shown in FIG. 5, except that the first transistor T1 connected to the initial signal line in this embodiment adopts a Top Gate structure.

In an exemplary implementation, the first conductive layer is not provided with a first connection electrode which serves as a first adapter electrode, the initial signal line 35 is arranged in the third conductive layer, and the initial signal line 35 located in the third conductive layer is connected to the first active layer located in the semiconductor layer through the fifteenth via V15 which serves as a single-hole structure via.

In an exemplary implementation, the structures of the second transistor T2 to the seventh transistor T7 in this embodiment are substantially the same as the structure in the embodiment shown in FIG. 5.

In an exemplary implementation, taking one circuit unit as an example, the manufacturing process of the display substrate in this embodiment may include the following operations.
(21) A pattern of a first conductive layer is formed. In an exemplary implementation, the process of forming the pattern of the first conductive layer and the structure of the first conductive layer are substantially the same as those shown in FIG. 7A, except that the first conductive layer of each circuit unit is not provided with a first connection electrode, as shown in FIG. 14.

In an exemplary implementation, the first conductive layer of each circuit unit in the display substrate may at least include the second connection electrode 12, the third connection electrode 13, the first electrode plate 51 of the storage capacitor, the data signal line 60, and the first power supply line 70. This structure is substantially the same as that in a foregoing embodiment.

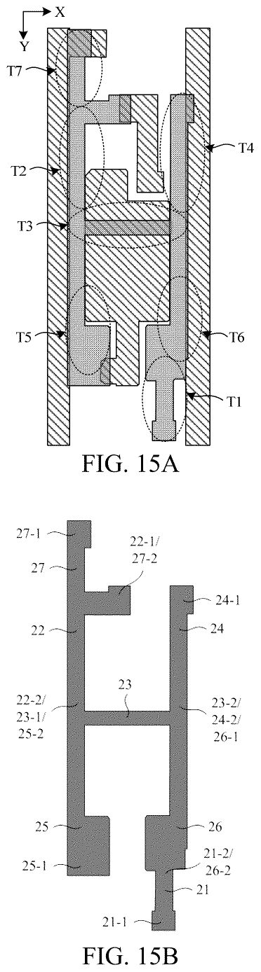

In an exemplary implementation, a second power supply connection block 72 may be arranged on the first power supply line 70, no first power supply connection block is arranged on the first power supply line 70, and no data connection block is arranged on the data signal line 60.
(22) A pattern of a semiconductor layer is formed. In an exemplary implementation, the process of forming the pattern of the semiconductor layer and the structure of the semiconductor layer are substantially the same as those shown in FIGS. 8A and 8B, as shown in FIGS. 15A and 15B, FIG. 15B being a planar schematic diagram of the semiconductor layer in FIG. 15A.

In an exemplary implementation, the pattern of the semiconductor layer of each circuit unit in the display substrate may include the first active layer 21 to the seventh active layer 27, and the first active layer 21 to the seventh active layer 27 are connected to each other to form an integrated structure. This structure is substantially the same as that in a foregoing embodiment.

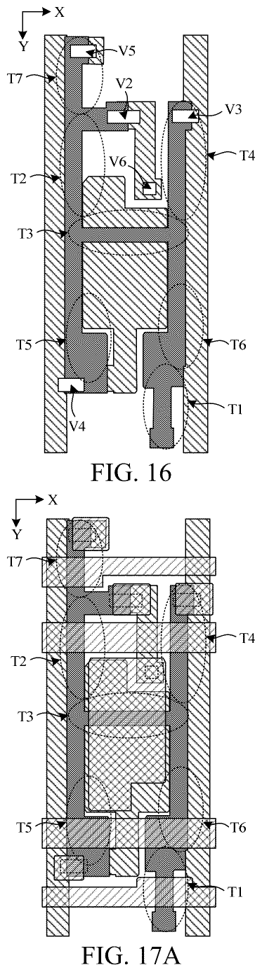

In an exemplary implementation, since the first conductive layer is not provided with a first connection electrode, the orthographic projection of the first region 21-1 of the first active layer on the base substrate does not overlap with the orthographic projection of the first conductive layer on the base substrate. The first conductive layer is not provided with a data connection block and a first power supply connection block, the orthographic projection of the first region 24-1 of the fourth active layer on the base substrate at least partially overlaps with the orthographic projection of the data signal line 60 on the base substrate, and the orthographic projection of the first region 25-1 of the fifth active layer on the base substrate at least partially overlaps with the orthographic projection of the first power supply line 70 on the base substrate.
(23) A pattern of a second insulating layer is formed. In an exemplary implementation, the process of forming the pattern of the second insulating layer and the structures of the plurality of vias are substantially the same as those shown in FIG. 9A, except that the plurality of vias in each circuit unit do not include a first via, as shown in FIG. 16.

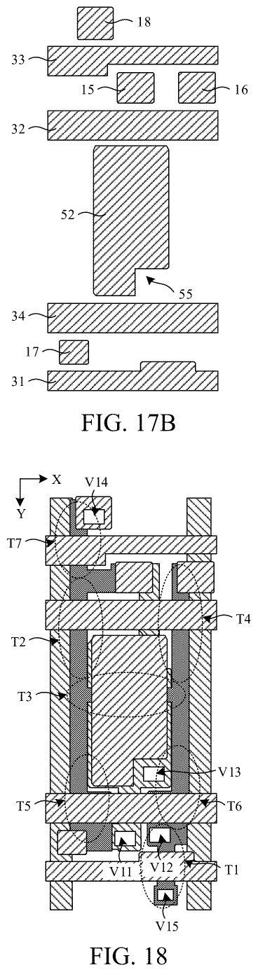

In an exemplary implementation, the plurality of vias of each circuit unit in the display substrate at least include the second via V2, the third via V3, the fourth via V4, the fifth via V5 and the sixth via V6, the second via V2 to the fifth via V5 are adapter structure vias, and the sixth via V6 is a single-hole structure. The structures of the vias are substantially the same as those in a foregoing embodiment, except that the third via V3 exposes the data signal line 60 and the first region of the fourth active layer at the same time, and the fourth via V4 exposes the first power supply line 70 and the first region of the fifth active layer at the same time.
(24) A pattern of a second conductive layer is formed. In an exemplary implementation, the process of forming the pattern of the second conductive layer and the structure of the second conductive layer are substantially the same as those shown in FIGS. 10A and 10B, except that the second conductive layer of each circuit unit is not provided with an initial signal line, as shown in FIGS. 17A and 17B, FIG. 17B being a schematic diagram of the second conductive layer in FIG. 17A.

In an exemplary implementation, the pattern of the second conductive layer of each circuit unit in the display substrate at least includes: the fifth connection electrode 15, the sixth connection electrode 16, the seventh connection electrode 17, the eighth connection electrode 18, the first scan signal line 31, the second scan signal line 32, the third scan signal line 33, the light emitting signal line 34, and the second electrode plate 52 of the storage capacitor. This structure is substantially the same as that in a foregoing embodiment, except that the sixth connection electrode 16 is simultaneously connected to the data signal line 60 and the first region of the fourth active layer through the third via V3, and the seventh connection electrode 17 is simultaneously connected to the first power supply line 70 and the first region of the fifth active layer through the fourth via V4.

In an exemplary implementation, the structures such as the data signal line and the first power supply line are arranged in the first conductive layer, the active layers of the plurality of transistors are arranged in the semiconductor layer, the structures such as the gate electrodes of the plurality of transistors and the plurality of connection electrodes are arranged in the second conductive layer, and the plurality of connection electrodes located in the second conductive layer realize connection between the semiconductor layer and the first conductive layer. Therefore, the second transistor T2, the fourth transistor T4, the fifth transistor T5 and the seventh transistor T7 are transistors of a Top Gate bottom connect (TGBC) structure.
(25) A pattern of a third insulating layer is formed. In an exemplary implementation, the process of forming the pattern of the third insulating layer and the structures of the plurality of vias are substantially the same as those shown in FIG. 11A, except that the plurality of vias of each circuit unit further include a fifteenth via V15, as shown in FIG. 18.

In an exemplary implementation, the plurality of vias in each circuit unit in the display substrate at least include: the eleventh via V11, the twelfth via V12, the thirteenth via V13, the fourteenth via V14 and the fifteenth via V15, and the structures of the eleventh via V11 to the fourteenth via V14 are substantially the same as those in a foregoing embodiment.

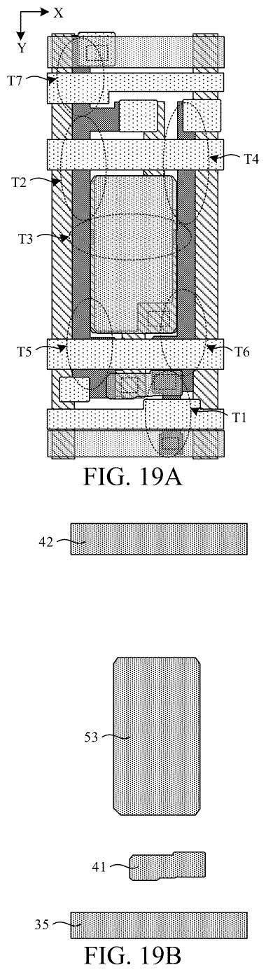

In an exemplary implementation, the orthographic projection of the fifteenth via V15 on the base substrate is located in the range of the orthographic projection of the first region of the first active layer on the base substrate, the third insulating layer in the fifteenth via V15 is etched away to expose the surface of the first region of the first active layer, and the fifteenth via V15 is configured such that the initial signal line formed subsequently is connected to the first region of the first active layer through this via.
(26) A pattern of a third conductive layer is formed. In an exemplary implementation, the process of forming the third conductive layer and the structure of the third conductive layer are substantially the same as those shown in FIGS. 12A and 12B, except that the third conductive layer of each circuit unit further includes an initial signal line, as shown in FIGS. 19A and 19B, FIG. 19B being a schematic diagram of the second conductive layer in FIG. 19A.

In an exemplary implementation, the third conductive layer of each circuit unit in the display substrate at least includes: the anode connection electrode 41, the power supply connection line 42, the third electrode plate 53 of the storage capacitor, and the initial signal line 35, and the structures of the anode connection electrode 41, the power supply connection line 42 and the third electrode plate 53 are substantially the same as those in a foregoing embodiment.

In an exemplary implementation, the initial signal line 35 may be in a shape of a straight line or a polyline extending in the first direction X and may be located on a side of the first scan signal line 31 away from the first electrode plate 51, and the initial signal line 35 may be connected to the first region of the first active layer through the fifteenth via V15, thereby realizing that the initial signal line 35 can write an initial signal to the first electrode of the first transistor T1.

In an exemplary implementation, the active layers of the plurality of transistors are arranged in the semiconductor layer, the gate electrodes of the plurality of transistors are arranged in the second conductive layer, the structures such as the anode connection electrode and the initial signal line are arranged in the third conductive layer, and the anode connection electrode and the initial signal line located in the third conductive layer are connected to the semiconductor layer. Therefore, the first transistor T1 and the sixth transistor T6 are transistors of a Top Gate structure.
(27) A pattern of a planarization layer is formed. In an exemplary implementation, the process of forming the pattern of the planarization layer and the structure of the anode via are substantially the same as those in a foregoing embodiment.

So far, a drive circuit layer has been prepared on the base substrate. In a plane parallel to the display substrate, the drive circuit layer may include a plurality of circuit units. Each of the circuit units may include a pixel drive circuit, and a first scan signal line, a second scan signal line, a third scan signal line, a light emitting signal line, an initial signal line, a data signal line and a first power supply line that are connected to the pixel drive circuit. In a plane perpendicular to the display substrate, the drive circuit layer may include a first conductive layer, a first insulating layer, a semiconductor layer, a second insulating layer, a second conductive layer, a third insulating layer, a third conductive layer and a planarization layer that are sequentially arranged on the base substrate. The first conductive layer may at least include a first electrode plate, a data signal line and a first power supply line. The semiconductor layer may at least include active layers of a plurality of oxide transistors. The second conductive layer may at least include a second electrode plate, a first scan signal line, a second scan signal line, a third scan signal line and a light emitting signal line. The third conductive layer may at least include a third electrode plate, an anode connection electrode, a power supply connection line and an initial signal line.

An embodiment of the present disclosure provides a display substrate in which a TGBC structure is combined with a Top Gate structure, which not only can reduce the occupied area of a pixel drive circuit, facilitating improving display resolution, but also reduces the complexity of a punching process, facilitating improving product yield. In the display substrate according to an embodiment of the present disclosure, the second transistor T2 connected to the second electrode plate, the fourth transistor T4 connected to the data signal line, and the fifth transistor T5 and the seventh transistor T7 connected to the first power supply line have a TGBC structure, and the first transistor T1 connected to the initial signal line and the sixth transistor T6 connected to the anode connection electrode have a Top Gate structure. Compared with a display substrate in which all transistors have a TGBC structure, in the display substrate of the present disclosure, the number of adapter structure vias is reduced from 6 to 4, which can effectively reduce the occupied area of the pixel drive circuit, effectively improving display resolution. In addition, reducing the number of adapter structure vias may lead to a reduction in the complexity of the punching process, which may reduce the production cost and effectively improve the product yield. Compared with a display substrate in which all transistors have a Top Gate structure, in the display substrate of the present disclosure, the data signal line and the first power supply line are arranged in the first conductive layer, which not only can reduce the coupling capacitance between the data signal line and the first power supply line and other signals, reducing crosstalk between signals, but also can effectively reduce the delay time RC of the data signal line, effectively reducing logic power consumption.

The technical effects of the structures in the embodiments of the present disclosure, such as the first capacitor and the second capacitor of a parallel structure forming the storage capacitor, the first power supply line and the power supply connection line forming a net-like structure, and the scan signal line and the light emitting signal line being arranged in the source-drain metal (SD) layer, are the same as those in foregoing embodiments, which will not be further described herein.

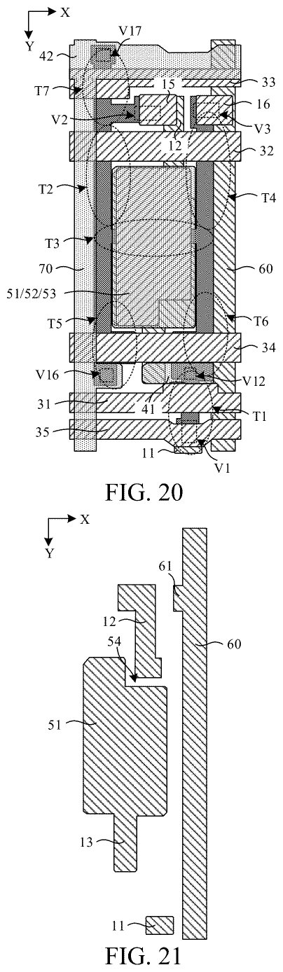

FIG. 20 is a schematic diagram of a planar structure of a further display substrate according to an exemplary embodiment of the present disclosure, illustrating a structure of one circuit unit. As shown in FIG. 20, in an exemplary implementation, the main body structure of the display substrate of this embodiment is substantially the same as the structure of the embodiment shown in FIG. 5, except that the fifth transistor T5 and the seventh transistor T7 connected to the first power supply line in this embodiment adopt a Top Gate structure.

In an exemplary implementation, the first conductive layer is not provided with a first power supply line, the first conductive layer is not provided with a seventh connection electrode and an eighth connection electrode, the first power supply line 70 is arranged in the third conductive layer, and the first power supply line 70 located in the third conductive layer is connected to the fifth active layer through a sixteenth via V16 which serves as a single-hole structure via, and is connected to the seventh active layer through a seventeenth via V17 which serves as a single-hole structure via.

In an exemplary implementation, the structures of the first transistor T1 to the fourth transistor T4 in this embodiment are substantially the same as the structure in the embodiment shown in FIG. 5.

In an exemplary implementation, the power supply connection line 42 and the first power supply line 70 may be connected to each other to form an integrated structure.

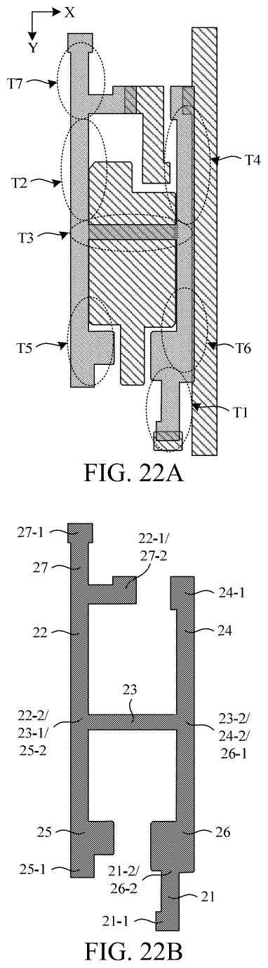

In an exemplary implementation, taking one circuit unit as an example, the manufacturing process of the display substrate in this embodiment may include the following operations.
(31) A pattern of a first conductive layer is formed. In an exemplary implementation, the process of forming the pattern of the first conductive layer and the structure of the first conductive layer are substantially the same as those shown in FIG. 7A, except that the first conductive layer of each circuit unit is not provided with a first power supply line, as shown in FIG. 21.

In an exemplary implementation, the first conductive layer of each circuit unit in the display substrate may at least include a first connection electrode 11, a second connection electrode 12, a third connection electrode 13, a first electrode plate 51 of a storage capacitor, and a data signal line 60 on which a data connection block 61 is arranged. This structure is substantially the same as that in a foregoing embodiment.
(32) A pattern of a semiconductor layer is formed. In an exemplary implementation, the process of forming the pattern of the semiconductor layer and the structure of the semiconductor layer are substantially the same as those shown in FIGS. 8A and 8B, as shown in FIGS. 22A and 22B, FIG. 22B being a planar schematic diagram of the semiconductor layer in FIG. 22A.

In an exemplary implementation, the pattern of the semiconductor layer of each circuit unit in the display substrate may include the first active layer 21 to the seventh active layer 27, and the first active layer 21 to the seventh active layer 27 are connected to each other to form an integrated structure. This structure is substantially the same as that in a foregoing embodiment.

In an exemplary implementation, the orthographic projection of the first region 21-1 of the first active layer on the base substrate at least partially overlaps with the orthographic projection of the first connection electrode 11 on the base substrate, and the orthographic projection of the first region 24-1 of the fourth active layer on the base substrate at least partially overlaps with the orthographic projection of the data connection block 61 on the base substrate.

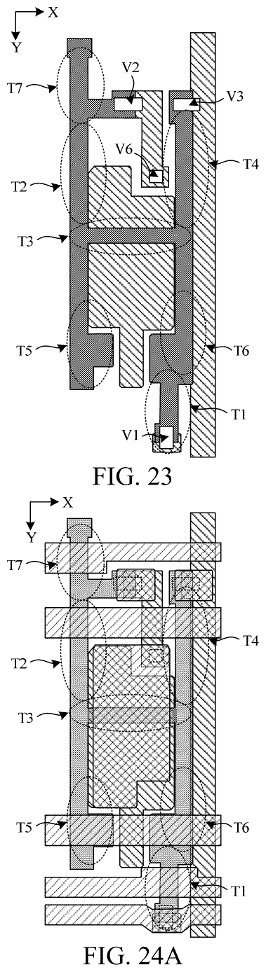

In an exemplary implementation, since the first conductive layer is not provided with a first power supply line, the orthographic projection of the first region 25-1 of the fifth active layer on the base substrate does not overlap with the orthographic projection of the first conductive layer on the base substrate, and the orthographic projection of the first region 27-1 of the seventh active layer on the base substrate does not overlap with the orthographic projection of the first conductive layer on the base substrate.
(33) A pattern of a second insulating layer is formed. In an exemplary implementation, the process of forming the pattern of the second insulating layer and the structures of the plurality of vias are substantially the same as those shown in FIG. 9A, except that the plurality of vias in each circuit unit do not include a fourth via and a fifth via, as shown in FIG. 23.

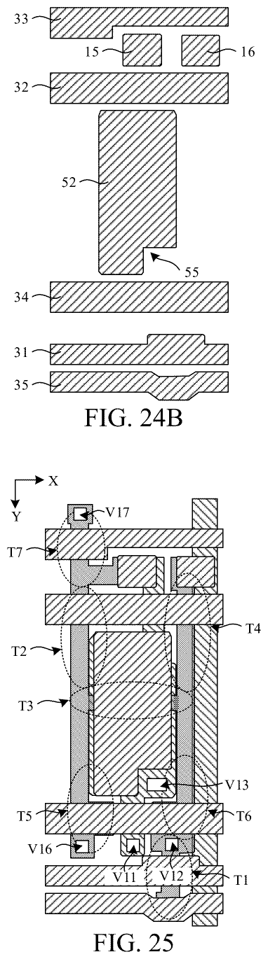

In an exemplary implementation, the plurality of vias of each circuit unit in the display substrate at least include: the first via V1, the second via V2, the third via V3 and the sixth via V6, the first via V1 to the third via V3 are adapter structure vias, and the sixth via V6 is a single-hole structure. The structures of the vias are substantially the same as those in a foregoing embodiment.
(34) A pattern of a second conductive layer is formed. In an exemplary implementation, the process of forming the pattern of the second conductive layer and the structure of the second conductive layer are substantially the same as those shown in FIGS. 10A and 10B, except that the second conductive layer of each circuit unit is not provided with a seventh connection electrode and an eighth connection electrode, as shown in FIGS. 24A and 24B, FIG. 24B being a schematic diagram of the second conductive layer in FIG. 24A.

In an exemplary implementation, the pattern of the second conductive layer of each circuit unit in the display substrate at least includes: a fifth connection electrode 15, a sixth connection electrode 16, a first scan signal line 31, a second scan signal line 32, a third scan signal line 33, a light emitting signal line 34, an initial signal line 35, and a second electrode plate 52 of a storage capacitor. This structure is substantially the same as that in a foregoing embodiment.

In an exemplary implementation, the structures such as the data signal line are arranged in the first conductive layer, the active layers of the plurality of transistors are arranged in the semiconductor layer, the structures such as the gate electrodes of the plurality of transistors, the plurality of connection electrodes, and the initial signal line are arranged in the second conductive layer, and the plurality of connection electrodes and the initial signal line located in the second conductive layer realize connection between the semiconductor layer and the first conductive layer. Therefore, the first transistor T1, the second transistor T2 and the fourth transistor T4 are transistors of a Top Gate bottom connect (TGBC) structure.
(35) A pattern of a third insulating layer is formed. In an exemplary implementation, the process of forming the pattern of the third insulating layer and the structures of the plurality of vias are substantially the same as those shown in FIG. 11A, except that the plurality of vias of each circuit unit further include a sixteenth via V16 and a seventeenth via V17, as shown in FIG. 25.

In an exemplary implementation, the plurality of vias in each circuit unit in the display substrate at least include: the eleventh via V11, the twelfth via V12, the thirteenth via V13, the sixteenth via V16 and the seventeenth via V17, and the structures of the eleventh via V11 to the thirteenth via V13 are substantially the same as those in a foregoing embodiment.

In an exemplary implementation, the orthographic projection of the sixteenth via V16 on the base substrate is located in the range of the orthographic projection of the first region of the fifth active layer on the base substrate, the third insulating layer in the sixteenth via V16 is etched away to expose the surface of the first region of the fifth active layer, and the sixteenth via V16 serves as a single-hole structure via in the present disclosure and is configured such that the first power supply line formed subsequently is connected to the first region of the fifth active layer through this via.

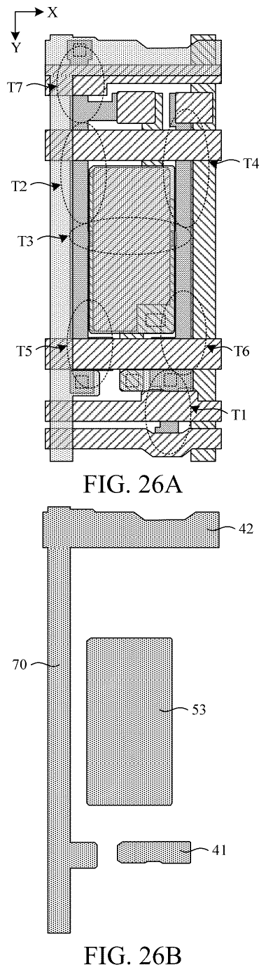

In an exemplary implementation, the orthographic projection of the seventeenth via V17 on the base substrate is located in the range of the orthographic projection of the first region of the seventh active layer on the base substrate, the third insulating layer in the seventeenth via V17 is etched away to expose the surface of the first region of the seventh active layer, and the seventeenth via V17 serves as a single-hole structure via in the present disclosure and is configured such that the first power supply line formed subsequently is connected to the first region of the seventh active layer through this via.
(36) A pattern of a third conductive layer is formed. In an exemplary implementation, the process of forming the third conductive layer and the structure of the third conductive layer are substantially the same as those shown in FIGS. 12A and 12B, except that the third conductive layer of each circuit unit further includes a power supply connection line 42 and a first power supply line 70, as shown in FIGS. 26A and 26B, FIG. 26B being a schematic diagram of the second conductive layer in FIG. 26A.

In an exemplary implementation, the third conductive layer of each circuit unit in the display substrate at least includes: an anode connection electrode 41, a power supply connection line 42, a third electrode plate 53 of a storage capacitor, and a first power supply line 70, and the structures of the anode connection electrode 41 and the third electrode plate 53 are substantially the same as those in a foregoing embodiment.

In an exemplary implementation, the first power supply line 70 may be in a shape of a straight line or a polyline extending in the second direction Y, and may be arranged on a side of the first electrode plate 51 in the opposite direction of the first direction X. The first power supply line 70 is connected to the first region of the fifth active layer through the sixteenth via V16 on the one hand, and to the first region of the seventh active layer through the seventeenth via V17 on the other hand, thus realizing that the first power supply line 70 can write a first power supply signal to the first electrode of the fifth transistor T5 and the first electrode of the seventh transistor T7.

In an exemplary implementation, the power supply connection line 42 may be in a shape of a straight line or a polyline extending in the first direction X, and may be arranged on a side of the third scan signal line 33 away from the second electrode plate 52, and the power supply connection line 42 is connected to the first power supply line 70, thus realizing mutual connection between the power supply connection line 42 whose main body portion extends in the first direction X and the first power supply line 70 whose main body portion extends in the second direction Y, and the power supply connection line 42 and the first power supply line 70 form a grid structure of a net-like connecting structure that transmits a first power supply signal on the display substrate.

In an exemplary implementation, the power supply connection line 42 and the first power supply line 70 may be connected to each other to form an integrated structure.

In an exemplary implementation, the active layers of the plurality of transistors are arranged in the semiconductor layer, the gate electrodes of the plurality of transistors are arranged in the second conductive layer, the structures such as the anode connection electrode and the first power supply line are arranged in the third conductive layer, and the anode connection electrode and the first power supply line located in the third conductive layer are connected to the semiconductor layer. Therefore, the fifth transistor T5, the sixth transistor T6 and the seventh transistor T7 are transistors of a Top Gate structure.
(37) A pattern of a planarization layer is formed. In an exemplary implementation, the process of forming the pattern of the planarization layer and the structure of the anode via are substantially the same as those in a foregoing embodiment.

So far, a drive circuit layer has been prepared on the base substrate. In a plane parallel to the display substrate, the drive circuit layer may include a plurality of circuit units. Each of the circuit units may include a pixel drive circuit, and a first scan signal line, a second scan signal line, a third scan signal line, a light emitting signal line, an initial signal line, a data signal line and a first power supply line that are connected to the pixel drive circuit. In a plane perpendicular to the display substrate, the drive circuit layer may include a first conductive layer, a first insulating layer, a semiconductor layer, a second insulating layer, a second conductive layer, a third insulating layer, a third conductive layer and a planarization layer that are sequentially arranged on the base substrate. The first conductive layer may at least include a first electrode plate and a data signal line. The semiconductor layer may at least include active layers of a plurality of oxide transistors. The second conductive layer may at least include a second electrode plate, a first scan signal line, a second scan signal line, a third scan signal line, a light emitting signal line and an initial signal line. The third conductive layer may at least include a third electrode plate, an anode connection electrode, a power supply connection line and a first power supply line.

An embodiment of the present disclosure provides a display substrate in which a TGBC structure is combined with a Top Gate structure, which not only can reduce the occupied area of a pixel drive circuit, facilitating improving display resolution, but also reduces the complexity of a punching process, facilitating improving product yield. In the display substrate in an embodiment of the present disclosure, the first transistor T1 connected to the initial signal line, the second transistor T2 connected to the second electrode plate, and the fourth transistor T4 connected to the data signal line have a TGBC structure; and the fifth transistor T5 connected to the first power supply line, the sixth transistor T6 connected to the anode connection electrode, and the seventh transistor T7 connected to the first power supply line have a Top Gate structure. Compared with a display substrate in which all transistors have a TGBC structure, in the display substrate of the present disclosure, the number of adapter structure vias is reduced from 6 to 3, which can effectively reduce the occupied area of the pixel drive circuit, effectively improving display resolution. In addition, reducing the number of adapter structure vias may lead to a reduction in the complexity of the punching process, which may reduce the production cost and effectively improve the product yield. Compared with a display substrate in which all transistors have a Top Gate structure, in the display substrate of the present disclosure, the data signal line is arranged in the first conductive layer, which not only can reduce the coupling capacitance between the data signal line and other signals, reducing crosstalk between signals, but also can effectively reduce the delay time RC of the data signal line, effectively reducing logic power consumption.

The technical effects of the structures in the embodiments of the present disclosure, such as the first capacitor and the second capacitor of a parallel structure forming the storage capacitor, the first power supply line and the power supply connection line forming a net-like structure, and the scan signal line and the light emitting signal line being arranged in the source-drain metal (SD) layer, are the same as those in foregoing embodiments, which will not be further described herein.

The aforementioned structure shown in the present disclosure and the preparation process thereof are merely exemplary description. In an exemplary implementation mode, corresponding structures may be changed and patterning processes may be added or reduced according to actual needs, which is not limited here in the present disclosure.

In an exemplary implementation mode, the display substrate according to the present disclosure may be applied to a display apparatus with a pixel drive circuit, such as an OLED, quantum dot display (QLED), light emitting diode display (Micro LED or Mini LED), or Quantum Dot Light Emitting Diode display (QDLED), which is not limited here in the present disclosure.

The present disclosure also provides a manufacturing method for a display substrate, for preparing the display substrate according to the foregoing embodiments. The display substrate includes a plurality of circuit units, at least one circuit unit includes a pixel drive circuit, and the pixel drive circuit at least includes a plurality of transistors. The manufacturing method may include:
forming a first conductive layer, a semiconductor layer, a second conductive layer and a third conductive layer sequentially on a base substrate and in a direction away from the base substrate, wherein the first conductive layer includes at least one first adapter electrode, the semiconductor layer includes active layers of a plurality of transistors, the second conductive layer includes at least one second adapter electrode, and the third conductive layer includes at least one third adapter electrode; the second adapter electrode is simultaneously connected to the first adapter electrode and the active layer of one transistor through an adapter structure via, the third adapter electrode is connected to the active layer of another transistor through a single-hole structure via, the adapter structure via includes a deep half hole and a shallow half hole, the deep half hole exposes the first adapter electrode, and the shallow half hole exposes the active layer.

A display apparatus which includes the aforementioned display substrate is also arranged in the present disclosure. The display apparatus may be any product or component with a display function, such as a mobile phone, a tablet computer, a television, a display, a laptop computer, a digital photo frame, and a navigator, which is not limited in the embodiments of the present invention.

Although implementation modes disclosed in the present disclosure are as above, it should be noted that the above implementation modes are exemplary only rather than restrictive. Therefore, the present disclosure is not limited to what is specifically shown and described herein. Various modifications, substitutions or omissions may be made in forms and details of implementation modes without departing from the scope of the present disclosure.

1. A display substrate, comprising: a plurality of circuit units, wherein
at least one circuit unit comprises a pixel drive circuit, and the pixel drive circuit at least comprises a plurality of transistors;
in a direction perpendicular to a plane of the display substrate, the display substrate at least comprises a first conductive layer, a semiconductor layer, a second conductive layer and a third conductive layer arranged on a base substrate and sequentially arranged in a direction away from the base substrate, the first conductive layer comprises at least one first adapter electrode, the semiconductor layer comprises active layers of a plurality of transistors, the second conductive layer comprises at least one second adapter electrode, and the third conductive layer comprises at least one third adapter electrode; and
the second adapter electrode is simultaneously connected to the first adapter electrode and an active layer of one transistor through an adapter structure via, the third adapter electrode is connected to an active layer of another transistor through a single-hole structure via, the adapter structure via comprises a deep half hole and a shallow half hole, the deep half hole exposes the first adapter electrode, and the shallow half hole exposes the active layers.

2. The display substrate according to claim 1, wherein
the plurality of transistors at least comprise a first transistor, the first transistor at least comprises a first active layer, and the first active layer is arranged in the semiconductor layer; and
the first conductive layer comprises a first connection electrode which serves as the first adapter electrode, the second conductive layer further comprises an initial signal line, and the initial signal line is simultaneously connected to the first connection electrode and the first active layer through an adapter structure via.

3. The display substrate according to claim 1, wherein
the plurality of transistors at least comprise a first transistor, the first transistor at least comprises a first active layer, and the first active layer is arranged in the semiconductor layer; and
the third conductive layer further comprises an initial signal line, and the initial signal line is connected to the first active layer through a single-hole structure via.

4. The display substrate according to claim 1, wherein
the plurality of transistors at least comprise a second transistor, the second transistor at least comprises a second active layer, and the second active layer is arranged in the semiconductor layer; and
the first conductive layer comprises a second connection electrode which serves as the first adapter electrode, the second conductive layer comprises a fifth connection electrode which serves as the second adapter electrode, and the fifth connection electrode is simultaneously connected to the second connection electrode and the second active layer through an adapter structure via.

5. The display substrate according to claim 1, wherein
the plurality of transistors at least comprise a fourth transistor, the fourth transistor at least comprises a fourth active layer, and the fourth active layer is arranged in the semiconductor layer; and
the first conductive layer further comprises a data signal line, the second conductive layer comprises a sixth connection electrode which serves as the second adapter electrode, and the sixth connection electrode is simultaneously connected to the data signal line and the fourth active layer through an adapter structure via.

6. The display substrate according to claim 1, wherein
the plurality of transistors at least comprise a fifth transistor, the fifth transistor at least comprises a fifth active layer, and the fifth active layer is arranged in the semiconductor layer; and
the first conductive layer further comprises a first power supply line, the second conductive layer comprises a seventh connection electrode which serves as the second adapter electrode, and the seventh connection electrode is simultaneously connected to the first power supply line and the fifth active layer through an adapter structure via.

7. The display substrate according to claim 1, wherein
the plurality of transistors at least comprise a fifth transistor, the fifth transistor at least comprises a fifth active layer, and the fifth active layer is arranged in the semiconductor layer; and
the third conductive layer further comprises a first power supply line, and the first power supply line is connected to the fifth active layer through a single-hole structure via.

8. The display substrate according to claim 1, wherein
the plurality of transistors at least comprise a sixth transistor, the sixth transistor at least comprises a sixth active layer, and the sixth active layer is arranged in the semiconductor layer; and
the third conductive layer comprises an anode connection electrode which serves as the third adapter electrode, and the anode connection electrode is connected to the sixth active layer through a single-hole structure via.

9. The display substrate according to claim 1, wherein
the plurality of transistors at least comprise a seventh transistor, the seventh transistor at least comprises a seventh active layer, and the seventh active layer is arranged in the semiconductor layer; and
the first conductive layer further comprises a first power supply line, the second conductive layer comprises an eighth connection electrode which serves as the second adapter electrode, and the eighth connection electrode is simultaneously connected to the first power supply line and the seventh active layer through an adapter structure via.

10. The display substrate according to claim 1, wherein
the plurality of transistors at least comprise a seventh transistor, the seventh transistor at least comprises a seventh active layer, and the seventh active layer is arranged in the semiconductor layer; and
the third conductive layer further comprises a first power supply line, and the first power supply line is connected to the seventh active layer through a single-hole structure via.

11. The display substrate according to claim 1, wherein at least one transistor comprises a gate electrode, and the gate electrode is arranged in the second conductive layer.

12. The display substrate according to claim 1, wherein
the pixel drive circuit further comprises a storage capacitor,
the storage capacitor at least comprises a first electrode plate arranged in the first conductive layer, a second electrode plate arranged in the second conductive layer, and a third electrode plate arranged in the third conductive layer,
an orthographic projection of the second electrode plate on a plane of the base substrate at least partially overlaps with an orthographic projection of the first electrode plate on the plane of the base substrate,
an orthographic projection of the third electrode plate on the plane of the base substrate at least partially overlaps with the orthographic projection of the second electrode plate on the plane of the base substrate, and
the first electrode plate is connected to the third electrode plate.

13. The display substrate according to claim 1, wherein
at least one circuit unit further comprises at least one power supply connection line extending in a first direction and at least one first power supply line extending in a second direction,
the first power supply line is connected to the power supply connection line to form a net-like connecting structure that transmits a first power supply signal, and
the first direction intersects the second direction.

14. The display substrate according to claim 13, wherein
the first power supply line is arranged in the first conductive layer,
the power supply connection line is arranged in the third conductive layer,
the second conductive layer comprises an eighth connection electrode which serves as the second adapter electrode,
the eighth connection electrode is connected to the first power supply line through a via, and
the power supply connection line is connected to the eighth connection electrode through a via.

15. The display substrate according to claim 13, wherein the first power supply line and the power supply connection line are arranged on a same layer and are connected to each other to form an integrated structure.

16. A display apparatus, comprising the display substrate according to claim 1.

17. A method for manufacturing a display substrate, wherein the display substrate comprises a plurality of circuit units, at least one circuit unit comprises a pixel drive circuit, and the pixel drive circuit at least comprises a plurality of transistors; the method comprising:
forming a first conductive layer, a semiconductor layer, a second conductive layer and a third conductive layer sequentially on a base substrate and in a direction away from the base substrate, wherein
the first conductive layer comprises at least one first adapter electrode, the semiconductor layer comprises active layers of a plurality of transistors, the second conductive layer comprises at least one second adapter electrode, and the third conductive layer comprises at least one third adapter electrode; and
the second adapter electrode is simultaneously connected to the first adapter electrode and an active layer of one transistor through an adapter structure via, the third adapter electrode is connected to an active layer of another transistor through a single-hole structure via, the adapter structure via comprises a deep half hole and a shallow half hole, the deep half hole exposes the first adapter electrode, and the shallow half hole exposes the active layers.
